(19) United States
(12) Patent Application Publication
(10) Pub. No.: US 2026/0031798 A1
(43) Pub. Date: Jan. 29, 2026

(54) FLIP-FLOP CIRCUIT AND PIXEL DRIVING CIRCUIT

(71) Applicant: BOE TECHNOLOGY GROUP CO., LTD., Beijing (CN)

(72) Inventors: Jinyu REN, Beijing (CN); Fangzhen ZHANG, Beijing (CN); Xinxing WANG, Beijing (CN)

(21) Appl. No.: 18/993,557

(22) PCT Filed: Apr. 17, 2024
(86) PCT No.: PCT/CN2024/088252

§ 371 Date: Jan. 12, 2025

(30) Foreign Application Priority Data
May 31, 2023 (CN) 202310638364.1

(51) Int. Cl. H03K 3/037; G09G 3/20; G09G 3/3233; H03K 3/017; H03K 19/20

(52) U.S. Cl. CPC H03K 3/037; G09G 3/2018; G09G 3/3233; H03K 3/017; G09G 2300/0814; G09G 2320/0233; G09G 2330/021; H03K 19/20

(57) ABSTRACT

A flip-flop circuit and a pixel driving circuit are provided, and belong to the field of circuit technology. The flip-flop circuit includes: an AND gate having a first input terminal, a second input terminal, and an output terminal, the AND gate is configured to control the output terminal to output a clock signal based on potentials at the first input terminal and the second input terminal, and a potential of the clock signal jumps between a first power supply voltage and a second power supply voltage; an input control sub-circuit configured to transmit the first power supply voltage or the second power supply voltage to at least one of the first input terminal and the second input terminal in response to an input control signal; and a duty cycle adjustment sub-circuit configured to adjust a duty cycle of the clock signal in response to a data voltage control signal.

### TECHNICAL FIELD

The present disclosure relates to the field of circuit technology, and in particular to a flip-flop circuit and a pixel driving circuit.

### BACKGROUND

A PAM (Pulse Amplitude Modulation) driving mode is a main driving mode for a grey scale of a current display product. With the continuous development of a series of display technologies such as LCD (Liquid Crystal Display), OLED (Organic Light Emitting Diode), LED (Light Emitting Diode), QD (Quantum Dot), disadvantages, such as having a high driving power consumption, generating a great amount of heat, incapable of realizing the low grey scale display, of the PAM driving mode are more and more prominent. Therefore, a PWM (Pulse Width Modulation) driving mode for a grey scale is introduced on the basis of the PAM driving mode for solving such the problems. The introduction of the PWM driving mode greatly increases the complexity of a driving circuit, which obstructs the development of advanced technologies, such as a high PPI (Pixels Per Inch), and a narrow border. In addition, the complex processes may reduce the yield and further increase the cost. The current PWM driving mode has a low driving frequency, which stings eyes to some extent. Therefore, it is necessary to further improve the current PWM driving mode, in order to achieve a healthy display. The current PWM driving mode is a full-screen driving mode, or a timing signal with a fixed duty ratio, which is introduced into a pixel driving circuit, is combined with the PAM driving mode to realize the low grey scale display. These two circuit designs increase the complexity of the driving circuit, and do not solve the problems of having a high power consumption, and generating a great amount of heat. In view of the above problems, it is urgently needed to develop a new driving circuit for a gray scale, to follow the development of the display technology.

### SUMMARY

The present invention is directed to at least one of the technical problems in the related art, and provides a flip-flop circuit and a pixel driving circuit.

In a first aspect, an embodiment of the present disclosure provides a flip-flop circuit, including: an AND gate having a first input terminal, a second input terminal, and an output terminal, wherein the AND gate is configured to control the output terminal to output a clock signal based on potentials at the first input terminal and the second input terminal, and a potential of the clock signal jumps between a first power supply voltage and a second power supply voltage; an input control sub-circuit configured to transmit the first power supply voltage or the second power supply voltage to at least one of the first input terminal and the second input terminal in response to an input control signal; and a duty cycle adjustment sub-circuit configured to adjust a duty cycle of the clock signal in response to a data voltage control signal.

In an embodiment, the duty cycle adjustment sub-circuit includes a control module and a duty cycle adjustment module; and a connection node connected between the control module and the duty ratio adjustment sub-circuit is a first node; the control module is configured to control a potential at the first node through the first power supply voltage or the second power supply voltage in response to the data voltage control signal; and the duty cycle adjustment module is configured to adjust the duty cycle of the clock signal output by the output terminal based on the potential at the first node.

In an embodiment, the flip-flop circuit further includes a reset sub-circuit configured to respond to a reset signal and reset the first node by the reset signal.

In an embodiment, the reset sub-circuit includes a second transistor, a control electrode of the second transistor is connected to a first electrode of the second transistor and a reset signal terminal, and a second electrode of the second transistor is connected to the first node.

In an embodiment, the first input terminal of the AND gate is electrically connected to a first power supply voltage terminal through the input control sub-circuit, and the second input terminal of the AND gate is directly connected to the first power supply voltage terminal; and the duty ratio adjustment module is connected to the first input terminal of the AND gate.

In an embodiment, the first input terminal and the second input terminal of the AND gate are connected to a first power supply voltage terminal through the input control sub-circuit.

In an embodiment, the input control sub-circuit includes a first transistor; the duty ratio adjustment module includes a third transistor, a first capacitor and a second capacitor; the control module includes a fourth transistor; the first transistor has the same switching characteristics as the third transistor, and switching characteristics of the third transistor and switching characteristics of the fourth transistor are opposite to each other; a control electrode of the first transistor is connected to an input control signal terminal, a first electrode of the first transistor is connected to the first power supply voltage terminal, and a second electrode of the first transistor is connected to the first input terminal; a control electrode of the third transistor is electrically connected to the first node and a first terminal of the second capacitor, a first electrode of the third transistor is connected to a second power supply voltage terminal and a second terminal of the second capacitor, and a second electrode of the third transistor is connected to a first terminal of the first capacitor and the first input terminal of the AND gate; and a second terminal of the first capacitor is connected to the first power supply voltage terminal or the second power supply voltage terminal; and a control electrode of the fourth transistor is connected to a data voltage control signal terminal, a first electrode of the fourth transistor is connected to the first power supply voltage terminal, and a second electrode of the fourth transistor is connected to the first node.

In an embodiment, the input control sub-circuit includes a first transistor; the duty ratio adjustment module includes a third transistor, a first capacitor and a second capacitor; the control module includes a fourth transistor, a ninth transistor and a tenth transistor; switching characteristics of the first transistor, the third transistor and the ninth transistor are the same, and the switching characteristics of the third transistor are opposite to those of the fourth transistor and the tenth transistor; a control electrode of the first transistor is connected to an input control signal terminal, a first electrode of the first transistor is connected to the first power supply voltage terminal, and a second electrode of the first transistor is connected to the first input terminal; a control electrode of the third transistor is electrically connected to the first node and a first terminal of the second capacitor, a first electrode of the third transistor is connected to the second power supply voltage terminal, and a second electrode of the third transistor is connected to a first terminal of the first capacitor and the first input terminal of the AND gate; a second terminal of the first capacitor is connected to the first power supply voltage terminal or the second power supply voltage terminal, and a second terminal of the second capacitor is connected to the second power supply voltage terminal; a control electrode of the fourth transistor is connected to a data voltage control signal terminal, a first electrode of the fourth transistor is connected to the first power supply voltage terminal and a second electrode of the tenth transistor, and a second electrode of the fourth transistor is connected to a first electrode of the ninth transistor and a first electrode of the tenth transistor; a control electrode of the ninth transistor is connected to a reset signal terminal, and a second electrode of the ninth transistor is connected to the first node; and a control electrode of the tenth transistor is connected to the first input terminal of the AND gate.

In an embodiment, the first input terminal of the AND gate is directly connected to the first power supply voltage terminal, and the second input terminal of the AND gate is electrically connected to the first power supply voltage terminal through the input control sub-circuit; and the duty ratio adjustment module is electrically connected to the second input terminal of the AND gate.

In an embodiment, the input control sub-circuit includes a first transistor; the duty ratio adjustment module includes a third transistor, a first capacitor and a second capacitor; the control module includes a fourth transistor; the first transistor has the same switching characteristics as the third transistor, and switching characteristics of the third transistor and switching characteristics of the fourth transistor are opposite to each other; a control electrode of the first transistor is connected to an input control signal terminal, a first electrode of the first transistor is connected to the first power supply voltage terminal, and a second electrode of the first transistor is connected to the second input terminal; a control electrode of the third transistor is electrically connected to the first node and a first terminal of the second capacitor, a first electrode of the third transistor is connected to a second power supply voltage terminal, and a second electrode of the third transistor is connected to a first terminal of the first capacitor and the first input terminal of the AND gate; a second terminal of the first capacitor is connected to the second power supply voltage terminal, and a second terminal of the second capacitor is connected to the second power supply voltage terminal; and a control electrode of the fourth transistor is connected to a data voltage control signal terminal, a first electrode of the fourth transistor is connected to the first power supply voltage terminal, and a second electrode of the fourth transistor is connected to the first node.

In an embodiment, the input control sub-circuit includes a first transistor; the duty ratio adjustment module includes a third transistor, a first capacitor and a second capacitor; the control module includes a fourth transistor, a ninth transistor and a tenth transistor; switching characteristics of the first transistor, the third transistor and the ninth transistor are the same, and the switching characteristics of the third transistor are opposite to those of the fourth transistor and the tenth transistor; a control electrode of the first transistor is connected to an input control signal terminal, a first electrode of the first transistor is connected to the first power supply voltage terminal, and a second electrode of the first transistor is connected to the second input terminal; a control electrode of the third transistor is electrically connected to the first node and a first terminal of the second capacitor, a first electrode of the third transistor is connected to the second power supply voltage terminal, and a second electrode of the third transistor is connected to a first terminal of the first capacitor and the second input terminal of the AND gate; a second terminal of the first capacitor is connected to the first power supply voltage terminal or the second power supply voltage terminal, and a second terminal of the second capacitor is connected to the second power supply voltage terminal; a control electrode of the fourth transistor is connected to a data voltage control signal terminal, a first electrode of the fourth transistor is connected to the first power supply voltage terminal and a second electrode of the tenth transistor, and a second electrode of the fourth transistor is connected to a first electrode of the ninth transistor and a first electrode of the tenth transistor; a control electrode of the ninth transistor is connected to a reset signal terminal, and a second electrode of the ninth transistor is connected to the first node; and a control electrode of the tenth transistor is connected to the second input terminal of the AND gate.

In an embodiment, the AND gate includes a fifth transistor, a sixth transistor, a seventh transistor, and an eighth transistor; switching characteristics of the fifth transistor and the sixth transistor are the same, switching characteristics of the seventh transistor and the eighth transistor are the same, and the switching characteristics of the fifth transistor and the seventh transistor are opposite to each other; a control electrode of the fifth transistor is connected to a control electrode of the eighth transistor as the first input terminal of the AND gate, a first electrode of the fifth transistor is connected to the first power supply voltage terminal, and a second electrode of the fifth transistor is connected to a first electrode of the sixth transistor; a control electrode of the sixth transistor is connected to a control electrode of the seventh transistor as the second input terminal of the AND gate, and a second electrode of the sixth transistor is connected to a second electrode of the seventh transistor and a second electrode of the eighth transistor as the output terminal of the AND gate; and a first electrode of the seventh transistor is connected to a first electrode of the eighth transistor and the second power supply voltage terminal.

In an embodiment, the AND gate includes a fifth transistor, a sixth transistor, a seventh transistor, and an eighth transistor; switching characteristics of the fifth transistor and the sixth transistor are the same, switching characteristics of the seventh transistor and the eighth transistor are the same, and the switching characteristics of the fifth transistor and the seventh transistor are opposite to each other; a control electrode of the fifth transistor is connected to a control electrode of the eighth transistor as the first input terminal of the AND gate, a first electrode of the fifth transistor is connected to the second power supply voltage terminal, and a second electrode of the fifth transistor is connected to a first electrode of the sixth transistor; a control electrode of the sixth transistor is connected to a control electrode of the seventh transistor as the second input terminal of the AND gate, and a second electrode of the sixth transistor is connected to a second electrode of the seventh transistor and a second electrode of the eighth transistor as the output terminal of the AND gate; and a first electrode of the seventh transistor is connected to a first electrode of the eighth transistor and the first power supply voltage terminal.

In an embodiment, the first input terminal of the AND gate is electrically connected to a second power supply voltage terminal through the input control sub-circuit, and the second input terminal of the AND gate is directly connected to the first power supply voltage terminal; and the duty ratio adjustment module is electrically connected to the first input terminal of the AND gate.

In an embodiment, the first input terminal and the second input terminal of the AND gate are electrically connected to the second power supply voltage terminal through the input control sub-circuit.

In an embodiment, the input control sub-circuit includes a first transistor; the duty ratio adjustment module includes a third transistor, a first capacitor and a second capacitor; the control module includes a fourth transistor; the first transistor has the same switching characteristics as the third transistor, and switching characteristics of the third transistor and switching characteristics of the fourth transistor are opposite to each other; a control electrode of the first transistor is connected to an input control signal terminal, a first electrode of the first transistor is connected to the first power supply voltage terminal, and a second electrode of the first transistor is connected to the first input terminal; a control electrode of the third transistor is electrically connected to the first node and a first terminal of the second capacitor, a first electrode of the third transistor is connected to a second power supply voltage terminal, and a second electrode of the third transistor is connected to a first terminal of the first capacitor and the first input terminal of the AND gate; a second terminal of the first capacitor is connected to the first power supply voltage terminal or the second power supply voltage terminal, and a second terminal of the second capacitor is connected to the second power supply voltage terminal; and a control electrode of the fourth transistor is connected to a data voltage control signal terminal, a first electrode of the fourth transistor is connected to the first power supply voltage terminal, and a second electrode of the fourth transistor is connected to the first node.

In an embodiment, the input control sub-circuit includes a first transistor; the duty ratio adjustment module includes a third transistor, a first capacitor and a second capacitor; the control module includes a fourth transistor, a ninth transistor and a tenth transistor; switching characteristics of the first transistor, the third transistor and the ninth transistor are the same, and the switching characteristics of the third transistor are opposite to those of the fourth transistor and the tenth transistor; a control electrode of the first transistor is connected to an input control signal terminal, a first electrode of the first transistor is connected to the first power supply voltage terminal, and a second electrode of the first transistor is connected to the first input terminal; a control electrode of the third transistor is electrically connected to the first node and a first terminal of the second capacitor, a first electrode of the third transistor is connected to the second power supply voltage terminal, and a second electrode of the third transistor is connected to a first terminal of the first capacitor and the first input terminal of the AND gate; a second terminal of the first capacitor is connected to the first power supply voltage terminal or the second power supply voltage terminal, and a second terminal of the second capacitor is connected to the second power supply voltage terminal; a control electrode of the fourth transistor is connected to a data voltage control signal terminal, a first electrode of the fourth transistor is connected to the first power supply voltage terminal and a second electrode of the tenth transistor, and a second electrode of the fourth transistor is connected to a first electrode of the ninth transistor and a first electrode of the tenth transistor; a control electrode of the ninth transistor is connected to a reset signal terminal, and a second electrode of the ninth transistor is connected to the first node; and a control electrode of the tenth transistor is connected to the first input terminal of the AND gate.

In an embodiment, the first input terminal of the AND gate is connected to the first power supply voltage terminal, and the second input terminal of the AND gate is electrically connected to a second power supply voltage terminal through the input control sub-circuit; and the duty ratio adjustment module is electrically connected to the second input terminal of the AND gate.

In an embodiment, the input control sub-circuit includes a first transistor; the duty ratio adjustment module includes a third transistor, a first capacitor and a second capacitor; the control module includes a fourth transistor; the first transistor has the same switching characteristics as the third transistor, and switching characteristics of the third transistor and switching characteristics of the fourth transistor are opposite to each other; a control electrode of the first transistor is connected to an input control signal terminal, a first electrode of the first transistor is connected to the first power supply voltage terminal, and a second electrode of the first transistor is connected to the second input terminal; a control electrode of the third transistor is electrically connected to the first node and a first terminal of the second capacitor, a first electrode of the third transistor is connected to a second power supply voltage terminal, and a second electrode of the third transistor is connected to a first terminal of the first capacitor and the first input terminal of the AND gate; a second terminal of the first capacitor is connected to the second power supply voltage terminal, and a second terminal of the second capacitor is connected to the second power supply voltage terminal; and a control electrode of the fourth transistor is connected to a data voltage control signal terminal, a first electrode of the fourth transistor is connected to the first power supply voltage terminal, and a second electrode of the fourth transistor is connected to the first node.

In an embodiment, the input control sub-circuit includes a first transistor; the duty ratio adjustment module includes a third transistor, a first capacitor and a second capacitor; the control module includes a fourth transistor, a ninth transistor and a tenth transistor; switching characteristics of the first transistor, the third transistor and the ninth transistor are the same, and the switching characteristics of the third transistor are opposite to those of the fourth transistor and the tenth transistor; a control electrode of the first transistor is connected to an input control signal terminal, a first electrode of the first transistor is connected to the first power supply voltage terminal, and a second electrode of the first transistor is connected to the second input terminal; a control electrode of the third transistor is electrically connected to the first node and a first terminal of the second capacitor, a first electrode of the third transistor is connected to the second power supply voltage terminal, and a second electrode of the third transistor is connected to a first terminal of the first capacitor and the second input terminal of the AND gate; a second terminal of the first capacitor is connected to the first power supply voltage terminal or the second power supply voltage terminal, and a second terminal of the second capacitor is connected to the second power supply voltage terminal; a control electrode of the fourth transistor is connected to a data voltage control signal terminal, a first electrode of the fourth transistor is connected to the first power supply voltage terminal and a second electrode of the tenth transistor, and a second electrode of the fourth transistor is connected to a first electrode of the ninth transistor and a first electrode of the tenth transistor; a control electrode of the ninth transistor is connected to a reset signal terminal, and a second electrode of the ninth transistor is connected to the first node; and a control electrode of the tenth transistor is connected to the second input terminal of the AND gate.

In an embodiment, the AND gate includes a fifth transistor, a sixth transistor, a seventh transistor, and an eighth transistor; switching characteristics of the fifth transistor and the sixth transistor are the same, switching characteristics of the seventh transistor and the eighth transistor are the same, and the switching characteristics of the fifth transistor and the seventh transistor are opposite to each other; a control electrode of the fifth transistor is connected to a control electrode of the eighth transistor as the first input terminal of the AND gate, a first electrode of the fifth transistor is connected to the first power supply voltage terminal, and a second electrode of the fifth transistor is connected to a first electrode of the sixth transistor; a control electrode of the sixth transistor is connected to a control electrode of the seventh transistor as the second input terminal of the AND gate, and a second electrode of the sixth transistor is connected to a second electrode of the seventh transistor and a second electrode of the eighth transistor as the output terminal of the AND gate; and a first electrode of the seventh transistor is connected to a first electrode of the eighth transistor and the second power supply voltage terminal.

In an embodiment, the AND gate includes a fifth transistor, a sixth transistor, a seventh transistor, and an eighth transistor; switching characteristics of the fifth transistor and the sixth transistor are the same, switching characteristics of the seventh transistor and the eighth transistor are the same, and the switching characteristics of the fifth transistor and the seventh transistor are opposite to each other; a control electrode of the fifth transistor is connected to a control electrode of the eighth transistor as the first input terminal of the AND gate, a first electrode of the fifth transistor is connected to the second power supply voltage terminal, and a second electrode of the fifth transistor is connected to a first electrode of the sixth transistor; a control electrode of the sixth transistor is connected to a control electrode of the seventh transistor as the second input terminal of the AND gate, and a second electrode of the sixth transistor is connected to a second electrode of the seventh transistor and a second electrode of the eighth transistor as the output terminal of the AND gate; and a first electrode of the seventh transistor is connected to a first electrode of the eighth transistor and the second power supply voltage terminal.

In a second aspect, an embodiment of the present disclosure provides a pixel driving circuit, including a driving transistor and a flip-flop circuit; wherein a control electrode of the driving transistor is connected to the flip-flop circuit; and the flip-flop circuit is the flip-flop circuit of any one of the above embodiments.

### BRIEF DESCRIPTION OF DRAWINGS

FIG. 1 is a schematic diagram of a flip-flop circuit in a first example of an embodiment of the present disclosure.

FIG. 2 is a schematic diagram of a flip-flop circuit in a second example of an embodiment of the present disclosure.

FIG. 3 is a schematic diagram of a flip-flop circuit in a third example of an embodiment of the present disclosure.

FIG. 4 is a schematic diagram of a flip-flop circuit in a fourth example of an embodiment of the present disclosure.

FIG. 5 is a schematic diagram of a flip-flop circuit in a fifth example of an embodiment of the present disclosure.

FIG. 6 is a schematic diagram of a flip-flop circuit in a sixth example of an embodiment of the present disclosure.

FIG. 7 is a schematic diagram of a flip-flop circuit in a seventh example of an embodiment of the present disclosure.

FIG. 8 is a schematic diagram of a flip-flop circuit in an eighth example of an embodiment of the present disclosure.

FIG. 9 is a schematic diagram of a flip-flop circuit in a ninth example of an embodiment of the present disclosure.

FIG. 10 is a schematic diagram of a flip-flop circuit in a tenth example of an embodiment of the present disclosure.

FIG. 11 is a schematic diagram of a flip-flop circuit in an eleventh example of an embodiment of the present disclosure.

FIG. 12 is a schematic diagram of a flip-flop circuit in a twelfth example of an embodiment of the present disclosure.

FIG. 13 is a schematic diagram of a flip-flop circuit in a thirteenth example of an embodiment of the present disclosure.

FIG. 14 is a schematic diagram of a flip-flop circuit in a fourteenth example of an embodiment of the present disclosure.

FIG. 15 is a schematic diagram of a flip-flop circuit in a fifteenth example of an embodiment of the present disclosure.

FIG. 16 is a schematic diagram of a flip-flop circuit in a sixteenth example of an embodiment of the present disclosure.

FIG. 17 is a schematic diagram of a flip-flop circuit in a seventeenth example of an embodiment of the present disclosure.

FIG. 18 is a schematic diagram of a flip-flop circuit in an eighteenth example of an embodiment of the present disclosure.

FIG. 19 is a schematic diagram of a flip-flop circuit in a nineteenth example of an embodiment of the present disclosure.

FIG. 20 is a schematic diagram of a flip-flop circuit in a twentieth example of an embodiment of the present disclosure.

FIG. 21 is a schematic diagram of a flip-flop circuit in a twenty-first example of an embodiment of the present disclosure.

FIG. 22 is a schematic diagram of a flip-flop circuit in a twenty-second example of an embodiment of the present disclosure.

FIG. 23 is a schematic diagram of a flip-flop circuit in a twenty-third example of an embodiment of the present disclosure.

FIG. 24 is a schematic diagram of a flip-flop circuit in a twenty-fourth example of an embodiment of the present disclosure.

FIG. 25 is a schematic diagram showing simulation results of the flip-flop circuit in each of the first example to the sixth example.

FIG. 26 is a schematic diagram showing simulation results of the flip-flop circuit in each of the seventh example to the twelfth example.

FIG. 27 is a schematic diagram showing simulation results of the flip-flop circuit in each of the thirteenth example to the eighteenth example.

FIG. 28 is a schematic diagram showing simulation results of the flip-flop circuit in each of the nineteenth example to the twenty-fourth example.

FIG. 29 is a schematic diagram of a pixel driving circuit according to an embodiment of the present disclosure.

### DETAIL DESCRIPTION OF EMBODIMENTS

In order to enable one of ordinary skill in the art to better understand the technical solutions of the present disclosure, the present disclosure will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term of “comprising”, “including”, or the like, means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

Before describing the embodiments of the present disclosure, it should be noted that in the embodiments of the present disclosure, (a magnitude of) a first power supply voltage is greater than (a magnitude of) a second power supply voltage. For example: (a magnitude of) the first power supply voltage is 8V and (a magnitude of) the second power supply voltage is −8V. That is, the first power supply voltage is a high-level signal with respect to the second power supply voltage, and the second power supply voltage is a low-level signal with respect to the first power supply voltage. However, a first power supply voltage terminal and a second power supply voltage terminal in the embodiments described below are configured to provide the first power supply voltage and the second power supply voltage, respectively. An input control signal and a reset signal in the embodiments described below are both high frequency scan signals.

In a first aspect, an embodiment of the present disclosure provides a flip-flop circuit capable of adjusting a duty cycle, including an AND gate, an input control sub-circuit, and a duty cycle adjustment sub-circuit.

The AND gate includes a first input terminal, a second input terminal, and an output terminal. The AND gate is configured to control the output terminal to output a clock signal based on potentials at the first input terminal and the second input terminal of the AND gate. A potential of the clock signal jumps between the first power supply voltage and the second power supply voltage. In this case, the AND gate may output the clock signal with the potential jumping between the first power supply voltage and the second power supply voltage.

The input control sub-circuit is configured to transmit the first power supply voltage or the second power supply voltage to at least one of the first input terminal and the second input terminal in response to an input control signal. That is, if the input control sub-circuit is connected to the first input terminal, it controls through the input control signal whether the received first power supply voltage or the received second power supply voltage may be transmitted to the first input terminal. If the input control sub-circuit is connected to the second input terminal, it controls through the input control signal whether the received first power supply voltage or the received second power supply voltage may be transmitted to the second input terminal.

The duty cycle adjustment sub-circuit is configured to adjust a duty cycle of the clock signal in response to a data voltage control signal. That is, the duty ratio adjustment sub-circuit may be controlled through the data voltage control signal, to adjust durations of the first power supply voltage and the second power supply voltage output from the output terminal of the AND gate for each clock cycle.

The flip-flop circuit provided by the embodiment of the present disclosure is provided with the duty cycle adjustment sub-circuit, which may generate the clock signal with the adjustable duty ratio. In this case, the flip-flop circuit may be applied to the pixel driving circuit, and a turn-on time of a driving transistor is controlled based on the clock signal generated by the flip-flop circuit, thereby controlling a brightness of a light emitting device.

In some examples, the duty cycle adjustment sub-circuit includes a control module and a duty cycle adjustment module. A connection node between the control module and the duty ratio adjustment sub-circuit is a first node. The control module is configured to charge the first node by the first power supply voltage in response to the data voltage control signal. The duty cycle adjustment module is configured to adjust the duty cycle of the clock signal output by the output terminal based on a potential at the first node.

Further, except for the above components, the flip-flop circuit in the embodiment of the present disclosure further includes a reset sub-circuit configured to respond to a rese signal and reset the first node by the reset signal. That is, before each clock cycle of the clock signal is started, the first node is reset, so that the duty ratio in each clock cycle can be accurately adjusted.

Further, the reset sub-circuit may include a second transistor, a control electrode of the second transistor is connected to a first electrode of the reset sub-circuit and a reset signal terminal, and a second electrode of the second transistor is connected to the first node. The reset signal terminal is configured to receive the reset signal. In the embodiment of the present disclosure, the reset signal is a high frequency signal. A timing of the reset signal and a timing of the input control signal are reciprocal with respect to each other. For example, the input control signal has a duty cycle of a low-level signal/a high-level signal=0.1 μs/99.9 μs, and the reset signal has a duty cycle of a low-level signal/a high-level signal=99.9 μs/0.1 μs.

In order to better understand the flip-flop circuit in the embodiment of the present disclosure, the flip-flop circuit in the embodiment of the present disclosure is specifically described below with reference to specific examples.

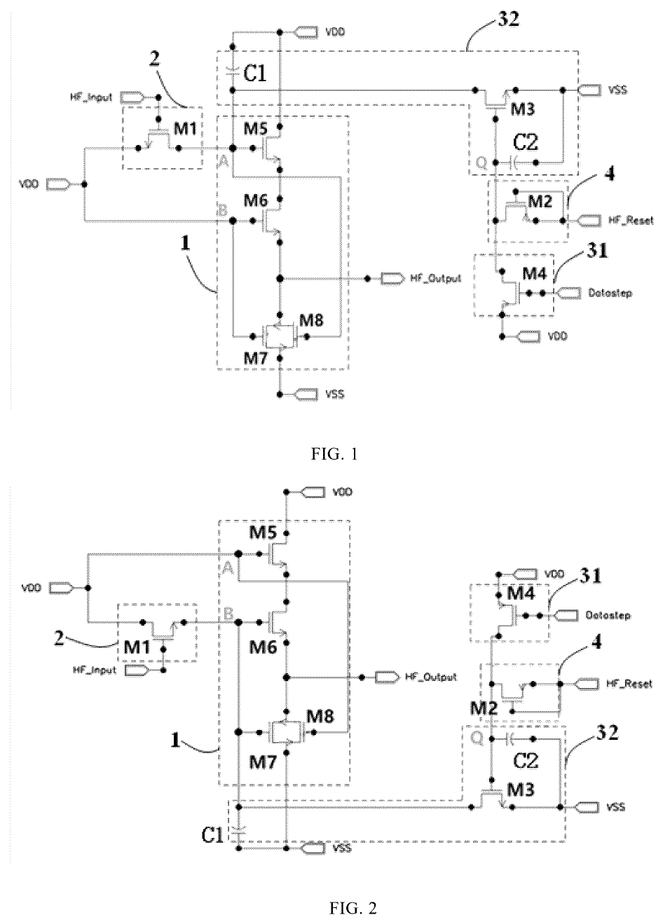

In a first example, FIG. 1 is a schematic diagram of a flip-flop circuit in a first example of an embodiment of the present disclosure. As shown in FIG. 1, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is electrically connected to a first power supply voltage terminal VDD through the input control sub-circuit, and a second input terminal B of the AND gate is directly connected to the first power supply voltage terminal VDD. The duty ratio adjustment module is connected to the first input terminal A of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The first transistor M1, the third transistor M3, the fifth transistor M5, and the sixth transistor M6 have the same switching characteristics (i.e., have the same conductivity type or have the same carrier type in their channels), the second transistor M2, the fourth transistor M4, the seventh transistor M7, and the eighth transistor M8 have the same switching characteristics, which are different from those of the first transistor. In this embodiment, as an example, the first transistor M1, the third transistor M3, the fifth transistor M5, and the sixth transistor M6 are N-type transistors, and the second transistor M2, the fourth transistor M4, the seventh transistor M7, and the eighth transistor M8 are P-type transistors.

Specifically, with continued reference to FIG. 1, a first electrode of the first transistor M1 is connected to the first power supply voltage terminal VDD, a second electrode of the first transistor M1 is connected to a control electrode of the fifth transistor M5 and a control electrode of the eighth transistor M8 as the first input terminal A of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the first power supply voltage terminal VDD, a second electrode of the fourth transistor M4 is connected to the first node, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to the first power supply voltage terminal VDD and a control electrode of the seventh transistor M7 as the second input terminal B of the AND gate. A second electrode of the seventh transistor M7 and a first electrode of the eighth transistor M8 are connected to each other, and connected to the second power supply voltage terminal VSS. A second terminal of the first capacitor C1 is connected to the first power supply voltage terminal VDD, and the second terminal of the second capacitor C2 is connected to the first node.

The flip-flop circuit in the first example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal=0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep=[7.42V, 7.4V, 7.3V, 7.2V, 7.1V, 7V, 7.42V, 6.9V, 6.8V, 6.7V], a capacitance of the first capacitor C1 is 20 fF and a capacitance of the second capacitor C2 is 20 pF. It should be understood that the above parameters may be adjusted based on actual requirements in use of an actual product.

Next, an operation of the flip-flop circuit in the first example is described. With continued reference to FIG. 1, a step of generating each clock cycle signal of a clock signal by using the flip-flop circuit in the first example includes the following stages.

In a first stage, i.e., an initial stage of the clock cycle, the reset signal written into the reset signal terminal HF_Reset is a low-level signal, so that the first node is reset to −20V, and the third transistor M3 is turned off in this stage.

In a second stage, the reset signal at the reset signal terminal HF_Reset is a high-level signal, the input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the output terminal HF_Output of the AND gate outputs a high-level signal. At the same time, the data voltage control signal written into the data voltage control signal terminal Datastep is written into the control electrode of the fourth transistor M4, and a charging speed for the first node (i.e., a speed for charging the first node) is controlled by controlling a turn-on degree of the fourth transistor M4 (i.e., a degree to which the fourth transistor M4 is turned on).

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, and the third transistor M3 is turned on, so that the second power supply voltage passes through the third transistor M3 to the first input terminal A of the AND gate, which therefore has the second power supply voltage, that is, a voltage at the first input terminal A of the AND gate is a low-level signal. At this time, the output terminal HF_Output of the AND gate outputs a low-level signal.

In a fourth stage, the reset signal at the reset signal terminal HF_Reset is a low-level signal, and the first node is reset to −20V. In this stage, the third transistor M3 is turned off, the first input terminal A of the AND gate retains a low-level signal, and the output terminal HF_Output still outputs the low-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In a second example, FIG. 2 is a schematic diagram of a flip-flop circuit in a second example of an embodiment of the present disclosure. As shown in FIG. 2, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is directly electrically connected to a first power supply voltage terminal VDD, and a second input terminal B of the AND gate is connected to the first power supply voltage terminal VDD through the input control sub-circuit. The duty ratio adjustment module is connected to the second input terminal B of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The first transistor M1, the third transistor M3, the fifth transistor M5, and the sixth transistor M6 have the same switching characteristics (i.e., have the same conductivity type or have the same carrier type in their channels), the second transistor M2, the fourth transistor M4, the seventh transistor M7, and the eighth transistor M8 have the same switching characteristics, which are different from those of the first transistor. In this embodiment, as an example, the first transistor M1, the third transistor M3, the fifth transistor M5, and the sixth transistor M6 are N-type transistors, and the second transistor M2, the fourth transistor M4, the seventh transistor M7, and the eighth transistor M8 are P-type transistors.

Specifically, with continued reference to FIG. 2, a first electrode of the first transistor M1 is connected to the first power supply voltage terminal VDD, a second electrode of the first transistor M1 is connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the second input terminal B of the AND gate, and a control electrode of the third transistor M3 is connected to the first node. A first electrode of the fourth transistor M4 is connected to the first power supply voltage terminal VDD, a second electrode of the fourth transistor M4 is connected to the first node, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6, a control electrode of the fifth transistor M5 is connected to a control electrode of the eighth transistor M8 as the first input terminal A of the AND gate, which is directly connected to a first power supply voltage terminal VDD. A second electrode of the sixth transistor M6 is connected to a first electrode of the seventh transistor M7 and a second electrode of the eighth transistor M8 as an output terminal HF_Output of the AND gate. A second electrode of the seventh transistor M7 and a first electrode of the eighth transistor M8 are connected to each other, and connected to the second power supply voltage terminal VSS. A second terminal of the first capacitor C1 is connected to the second power supply voltage terminal VSS, and the second terminal of the second capacitor C2 is connected to the first node.

The flip-flop circuit in the second example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal=0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep=[7.42V, 7.4V, 7.3V, 7.2V, 7.1V, 7V, 6.9V, 6.8V, 6.7V], a capacitance of the first capacitor C1 is 20 fF and a capacitance of the second capacitor C2 is 20 pF. It should be understood that the above parameters may be adjusted based on actual requirements in use of an actual product.

Next, an operation of the flip-flop circuit in the second example is described. With continued reference to FIG. 2, a step of generating each clock cycle signal of a clock signal by using the flip-flop circuit in the second example includes:

In a first stage, i.e., an initial stage of the clock cycle, the reset signal written into the reset signal terminal HF_Reset is a low-level signal, so that the first node is reset to −20V, and the third transistor M3 is turned off in this stage.

In a second stage, the reset signal at the reset signal terminal HF_Reset is a high-level signal, the input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the output terminal HF_Output of the AND gate outputs a high-level signal. At the same time, the data voltage control signal written into the data voltage control signal terminal Datastep is written into the control electrode of the fourth transistor M4, and a charging speed for the first node is controlled by controlling a turn-on degree of the fourth transistor M4.

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, which turns on the third transistor M3, so that the second power supply voltage passes through the third transistor M3 to the first input terminal A of the AND gate, which therefore has the second power supply voltage, that is, a voltage at the first input terminal A of the AND gate is a low-level signal. At this time, the output terminal HF_Output of the AND gate outputs a low-level signal.

In a fourth stage, the reset signal at the reset signal terminal HF_Reset is a low-level signal, and the first node is reset to −20V. In this stage, the third transistor M3 is turned off, the second input terminal B of the AND gate retains a low-level signal, and the output terminal HF_Output still outputs the low-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

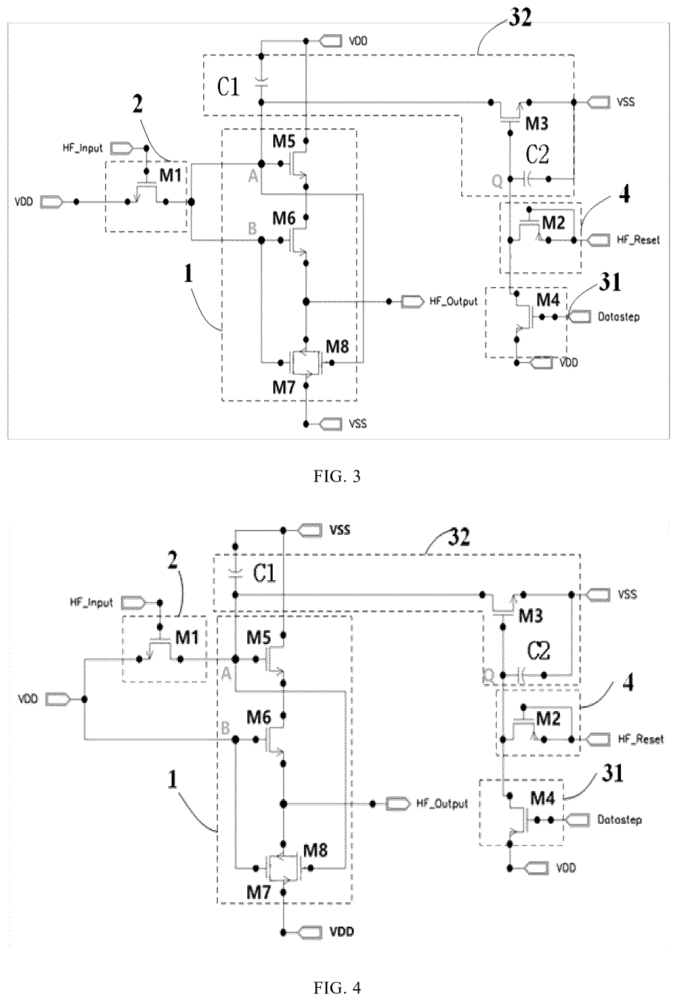

In a third example, FIG. 3 is a schematic diagram of a flip-flop circuit in a third example of an embodiment of the present disclosure. As shown in FIG. 3, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A and a second input terminal B of the AND gate are electrically connected to a first power supply voltage terminal VDD through the input control sub-circuit.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The first transistor M1, the third transistor M3, the fifth transistor M5, and the sixth transistor M6 have the same switching characteristics (i.e., have the same conductivity type or have the same carrier type in their channels), the second transistor M2, the fourth transistor M4, the seventh transistor M7, and the eighth transistor M8 have the same switching characteristics, which are different from those of the first transistor. In this embodiment, as an example, the first transistor M1, the third transistor M3, the fifth transistor M5, and the sixth transistor M6 are N-type transistors, and the second transistor M2, the fourth transistor M4, the seventh transistor M7, and the eighth transistor M8 are P-type transistors.

Specifically, with continued reference to FIG. 3, a first electrode of the first transistor M1 is connected to the first power supply voltage terminal VDD, a second electrode of the first transistor M1 is connected to a control electrode of the fifth transistor M5 and a control electrode of the eighth transistor M8 as the first input terminal A of the AND gate, the second electrode of the first transistor M1 is also connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the first power supply voltage terminal VDD, a second electrode of the fourth transistor M4 is connected to the first node, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to the first power supply voltage terminal VDD and a control electrode of the seventh transistor M7 as the second input terminal B of the AND gate. A second electrode of the seventh transistor M7 and a first electrode of the eighth transistor M8 are connected to each other, and connected to the second power supply voltage terminal VSS. A second terminal of the first capacitor C1 is connected to the first power supply voltage terminal VDD, and the second terminal of the second capacitor C2 is connected to the first node.

The flip-flop circuit in the third example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal=0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep=[7.42V, 7.4V, 7.3V, 7.2V, 7.1V, 7V, 7.42V, 6.9V, 6.8V, 6.7V], a capacitance of the first capacitor C1 is 20 fF and a capacitance of the second capacitor C2 is 20 pF. It should be understood that the above parameters may be adjusted based on actual requirements in use of an actual product.

Next, an operation of the flip-flop circuit in the third example is described. With continued reference to FIG. 3, a step of generating each clock cycle signal of a clock signal by using the flip-flop circuit in the third example includes the following stages.

In a first stage, i.e., an initial stage of the clock cycle, the reset signal written into the reset signal terminal HF_Reset is a low-level signal, so that the first node is reset to −20V, and the third transistor M3 is turned off in this stage.

In a second stage, the reset signal at the reset signal terminal HF_Reset is a high-level signal, the input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the output terminal HF_Output of the AND gate outputs a high-level signal. At the same time, the data voltage control signal written into the data voltage control signal terminal Datastep is written into the control electrode of the fourth transistor M4, and a charging speed for the first node is controlled by controlling a turn-on degree of the fourth transistor M4.

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, which turns on the third transistor M3, so that the second power supply voltage passes through the third transistor M3 to the first input terminal A of the AND gate, which therefore has the second power supply voltage, that is, a voltage at the first input terminal A of the AND gate is a low-level signal. At this time, the output terminal HF_Output of the AND gate outputs a low-level signal.

In a fourth stage, the reset signal at the reset signal terminal HF_Reset is a low-level signal, and the first node is reset to −20V. In this stage, the third transistor M3 is turned off, the first input terminal A of the AND gate retains a low-level signal, and the output terminal HF_Output still outputs the low-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In a fourth example, FIG. 4 is a schematic diagram of a flip-flop circuit in a fourth example of an embodiment of the present disclosure. As shown in FIG. 4, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is electrically connected to a first power supply voltage terminal VDD through the input control sub-circuit, and a second input terminal B of the AND gate is directly connected to the first power supply voltage terminal VDD. The duty ratio adjustment module is connected to the first input terminal A of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The first transistor M1, the third transistor M3, the fifth transistor M5, and the sixth transistor M6 have the same switching characteristics (i.e., have the same conductivity type or have the same carrier type in their channels), the second transistor M2, the fourth transistor M4, the seventh transistor M7, and the eighth transistor M8 have the same switching characteristics, which are different from those of the first transistor. In this embodiment, as an example, the first transistor M1, the third transistor M3, the fifth transistor M5, and the sixth transistor M6 are N-type transistors, and the second transistor M2, the fourth transistor M4, the seventh transistor M7, and the eighth transistor M8 are P-type transistors.

Specifically, with continued reference to FIG. 4, a first electrode of the first transistor M1 is connected to the first power supply voltage terminal VDD, a second electrode of the first transistor M1 is connected to a control electrode of the fifth transistor M5 and a control electrode of the eighth transistor M8 as the first input terminal A of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the first power supply voltage terminal VDD, a second electrode of the fourth transistor M4 is connected to the first node, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to the first power supply voltage terminal VDD and a control electrode of the seventh transistor M7 as the second input terminal B of the AND gate. A second electrode of the seventh transistor M7 and a first electrode of the eighth transistor M8 are connected to each other, and connected to the first power supply voltage terminal VDD. A second terminal of the first capacitor C1 is connected to the second power supply voltage terminal VSS, and the second terminal of the second capacitor C2 is connected to the first node.

The flip-flop circuit in the fourth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal=0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep=[7.42V, 7.4V, 7.3V, 7.2V, 7.1V, 7V, 7.42V, 6.9V, 6.8V, 6.7V], a capacitance of the first capacitor C1 is 20 fF and a capacitance of the second capacitor C2 is 20 pF. It should be understood that the above parameters may be adjusted based on actual requirements in use of an actual product.

Next, an operation of the flip-flop circuit in the fourth example is described. With continued reference to FIG. 4, a step of generating each clock cycle signal of a clock signal by using the flip-flop circuit in the fourth example includes:

In a first stage, i.e., an initial stage of the clock cycle, the reset signal written into the reset signal terminal HF_Reset is a low-level signal, so that the first node is reset to −20V, and the third transistor M3 is turned off in this stage.

In a second stage, the reset signal at the reset signal terminal HF_Reset is a high-level signal, the input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the output terminal HF_Output of the AND gate outputs a low-level signal. At the same time, the data voltage control signal written into the data voltage control signal terminal Datastep is written into the control electrode of the fourth transistor M4, and a charging speed for the first node is controlled by controlling a turn-on degree of the fourth transistor M4.

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, which turns on the third transistor M3, so that the second power supply voltage passes through the third transistor M3 to the first input terminal A of the AND gate, which therefore has the second power supply voltage, that is, a voltage at the first input terminal A of the AND gate is a low-level signal. The fifth transistor M5 is turned off, and the eighth transistor M8 is turned on. At this time, the output terminal HF_Output of the AND gate outputs the first power supply voltage, that is, a high-level signal.

In a fourth stage, the reset signal at the reset signal terminal HF_Reset is a low-level signal, and the first node is reset to −20V. In this stage, the third transistor M3 is turned off, the first input terminal A of the AND gate retains a low-level signal, and the output terminal HF_Output still outputs the high-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

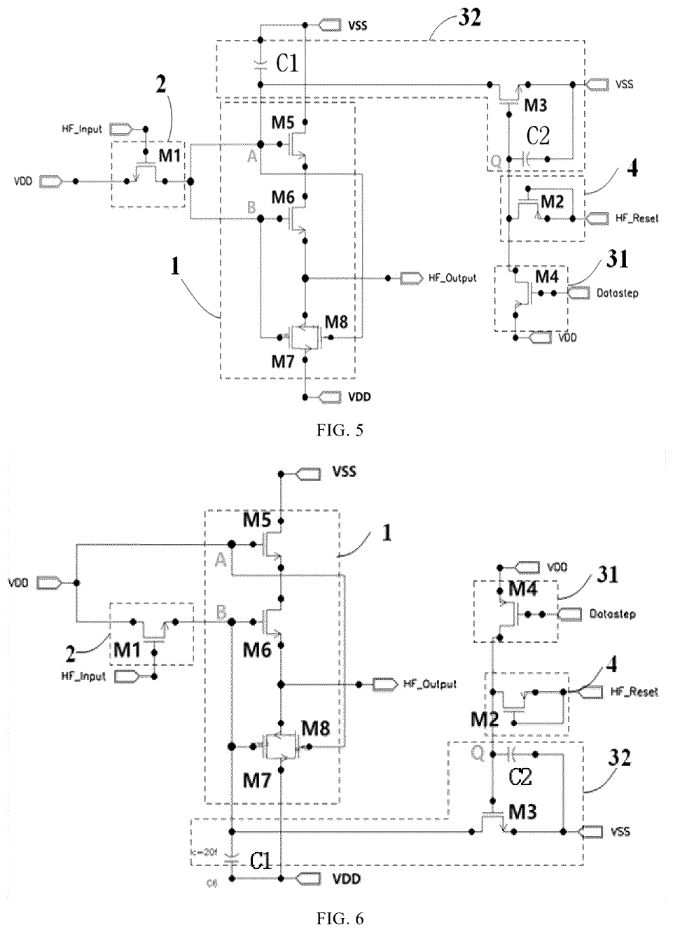

In a fifth example, FIG. 5 is a schematic diagram of a flip-flop circuit in a fifth example of an embodiment of the present disclosure. As shown in FIG. 5, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is directly electrically connected to a first power supply voltage terminal VDD, and a second input terminal B of the AND gate is connected to the first power supply voltage terminal VDD through the input control sub-circuit. The duty ratio adjustment module is connected to the second input terminal B of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The first transistor M1, the third transistor M3, the fifth transistor M5, and the sixth transistor M6 have the same switching characteristics (i.e., have the same conductivity type or have the same carrier type in their channels), the second transistor M2, the fourth transistor M4, the seventh transistor M7, and the eighth transistor M8 have the same switching characteristics, which are different from those of the first transistor. In this embodiment, as an example, the first transistor M1, the third transistor M3, the fifth transistor M5, and the sixth transistor M6 are N-type transistors, and the second transistor M2, the fourth transistor M4, the seventh transistor M7, and the eighth transistor M8 are P-type transistors.

Specifically, with continued reference to FIG. 5, a first electrode of the first transistor M1 is connected to the first power supply voltage terminal VDD, a second electrode of the first transistor M1 is connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the first power supply voltage terminal VDD, a second electrode of the fourth transistor M4 is connected to the first node, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6, a control electrode of the fifth transistor M5 is connected to a control electrode of the eighth transistor M8 as the first input terminal A of the AND gate. A second electrode of the sixth transistor M6 is connected to a first electrode of the seventh transistor M7 and a second electrode of the eighth transistor M8 as an output terminal HF_Output of the AND gate. A second electrode of the seventh transistor M7 and a first electrode of the eighth transistor M8 are connected to each other, and connected to the first power supply voltage terminal VDD. A second terminal of the first capacitor C1 is connected to the second power supply voltage terminal VSS, and the first terminal of the second capacitor C2 is connected to the first node.

The flip-flop circuit in the fifth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal=0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep=[7.42V, 7.4V, 7.3V, 7.2V, 7.1V, 7V, 7.42V, 6.9V, 6.8V, 6.7V], a capacitance of the first capacitor C1 is 20 fF and a capacitance of the second capacitor C2 is 20 pF. It should be understood that the above parameters may be adjusted based on actual requirements in use of an actual product.

Next, an operation of the flip-flop circuit in the fifth example is described. With continued reference to FIG. 5, a step of generating each clock cycle signal of a clock signal by using the flip-flop circuit in the fifth example includes the following stages.

In a first stage, i.e., an initial stage of the clock cycle, the reset signal written into the reset signal terminal HF_Reset is a low-level signal, so that the first node is reset to −20V, and the third transistor M3 is turned off in this stage.

In a second stage, the reset signal at the reset signal terminal HF_Reset is a high-level signal, the input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the output terminal HF_Output of the AND gate outputs the second power supply voltage, that is, a low-level signal. At the same time, the data voltage control signal written into the data voltage control signal terminal Datastep is written into the control electrode of the fourth transistor M4, and a charging speed for the first node is controlled by controlling a turn-on degree of the fourth transistor M4.

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, which turns on the third transistor M3, so that the second power supply voltage passes through the third transistor M3 to the first input terminal A of the AND gate, which therefore has the second power supply voltage, that is, a voltage at the first input terminal A of the AND gate is a low-level signal. At this time, the seventh transistor M7 is turned off, and the eighth transistor M8 is turned on, and the output terminal HF_Output of the AND gate outputs the first power supply voltage, that is, a high-level signal.

In a fourth stage, the reset signal at the reset signal terminal HF_Reset is a low-level signal, and the first node is reset to −20V. In this stage, the third transistor M3 is turned off, the second input terminal B of the AND gate retains a low-level signal, and the output terminal HF_Output still outputs the high-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In a sixth example, FIG. 6 is a schematic diagram of a flip-flop circuit in a sixth example of an embodiment of the present disclosure. As shown in FIG. 6, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A and a second input terminal B of the AND gate are electrically connected to a first power supply voltage terminal VDD through the input control sub-circuit.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The first transistor M1, the third transistor M3, the fifth transistor M5, and the sixth transistor M6 have the same switching characteristics (i.e., have the same conductivity type or have the same carrier type in their channels), the second transistor M2, the fourth transistor M4, the seventh transistor M7, and the eighth transistor M8 have the same switching characteristics, which are different from those of the first transistor. In this embodiment, as an example, the first transistor M1, the third transistor M3, the fifth transistor M5, and the sixth transistor M6 are N-type transistors, and the second transistor M2, the fourth transistor M4, the seventh transistor M7, and the eighth transistor M8 are P-type transistors.

Specifically, with continued reference to FIG. 6, a first electrode of the first transistor M1 is connected to the first power supply voltage terminal VDD, a second electrode of the first transistor M1 is connected to a control electrode of the fifth transistor M5 and a control electrode of the eighth transistor M8 as the first input terminal A of the AND gate, the second electrode of the first transistor M1 is also connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the first power supply voltage terminal VDD, a second electrode of the fourth transistor M4 is connected to the first node, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to a control electrode of the seventh transistor M7 and a first plate of the first capacitor C1 as the second input terminal B of the AND gate. A second electrode of the seventh transistor M7 and a first electrode of the eighth transistor M8 are connected to each other, and connected to the first power supply voltage terminal VDD. A second plate of the first capacitor C1 is connected to the first power supply voltage terminal VDD, and the second plate of the second capacitor C2 is connected to the first node.

The flip-flop circuit in the sixth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal=0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep=[7.42V, 7.4V, 7.3V, 7.2V, 7.1V, 7V, 7.42V, 6.9V, 6.8V, 6.7V], a capacitance of the first capacitor C1 is 20 fF and a capacitance of the second capacitor C2 is 20 pF. It should be understood that the above parameters may be adjusted based on actual requirements in use of an actual product.

Next, an operation of the flip-flop circuit in the sixth example is described. With continued reference to FIG. 6, a step of generating each clock cycle signal of a clock signal by using the flip-flop circuit in the sixth example includes:

In a first stage, i.e., an initial stage of the clock cycle, the reset signal written into the reset signal terminal HF_Reset is a low-level signal, so that the first node is reset to −20V, and the third transistor M3 is turned off in this stage.

In a second stage, the reset signal at the reset signal terminal HF_Reset is a high-level signal, the input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the output terminal HF_Output of the AND gate outputs the second power supply voltage, that is, a low-level signal. At the same time, the data voltage control signal written into the data voltage control signal terminal Datastep is written into the control electrode of the fourth transistor M4, and a charging speed for the first node is controlled by controlling a turn-on degree of the fourth transistor M4.

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, which turns on the third transistor M3, so that the second power supply voltage passes through the third transistor M3 to the first input terminal A of the AND gate, which therefore has the second power supply voltage, that is, a voltage at the first input terminal A of the AND gate is a low-level signal. At this time, the fifth transistor M5 is turned off, and the eighth transistor M8 is turned on, and the output terminal HF_Output of the AND gate outputs the first power supply voltage, that is, a high-level signal.

In a fourth stage, the reset signal at the reset signal terminal HF_Reset is a low-level signal, and the first node is reset to −20V. In this stage, the third transistor M3 is turned off, the first input terminal A of the AND gate retains a low-level signal, and the output terminal HF_Output still outputs the high-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

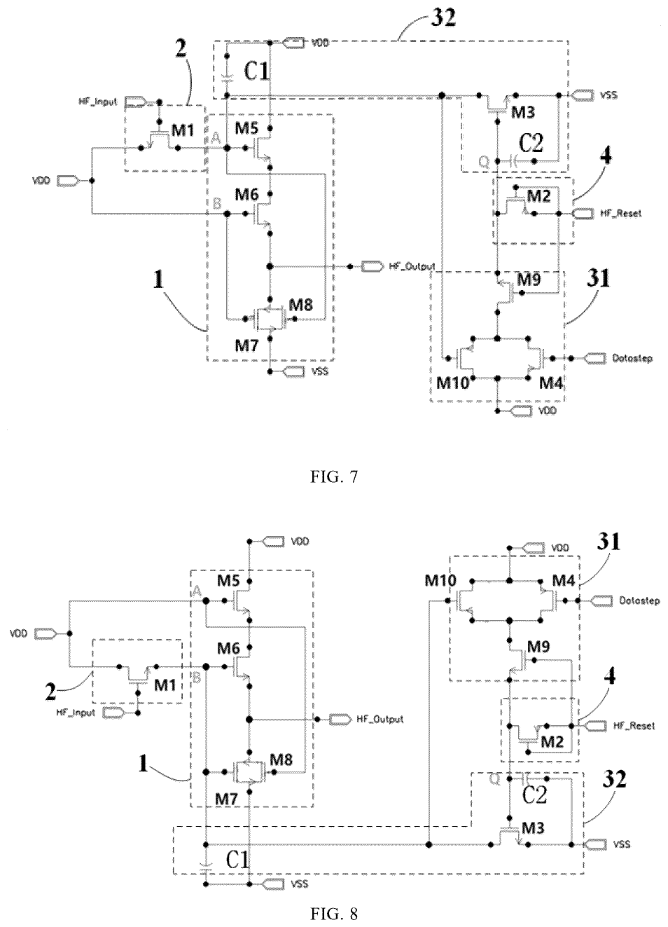

In a seventh example, FIG. 7 is a schematic diagram of a flip-flop circuit in a seventh example of an embodiment of the present disclosure. As shown in FIG. 7, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is electrically connected to a first power supply voltage terminal VDD through the input control sub-circuit, and a second input terminal B of the AND gate is directly connected to the first power supply voltage terminal VDD. The duty ratio adjustment module is connected to the first input terminal A of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The first transistor M1, the third transistor M3, the fifth transistor M5, the sixth transistor M6 and the ninth transistor M9 have the same switching characteristics, the second transistor M2, the fourth transistor M4, the seventh transistor M7, the eighth transistor M8 and the tenth transistor M10 have the same switching characteristics, which are different from those of the first transistor. In this embodiment, as an example, the first transistor M1, the third transistor M3, the fifth transistor M5, the sixth transistor M6 and the ninth transistor M9 are N-type transistors, and the second transistor M2, the fourth transistor M4, the seventh transistor M7, the eighth transistor M8 and the tenth transistor M10 are P-type transistors.

Specifically, with continued reference to FIG. 7, a first electrode of the first transistor M1 is connected to the first power supply voltage terminal VDD, a second electrode of the first transistor M1 is connected to a control electrode of the fifth transistor M5 and a control electrode of the eighth transistor M8 as the first input terminal A of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the first power supply voltage terminal VDD, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to the first power supply voltage terminal VDD and a control electrode of the seventh transistor M7 as the second input terminal B of the AND gate. A second electrode of the seventh transistor M7 and a first electrode of the eighth transistor M8 are connected to each other, and connected to the second power supply voltage terminal VSS. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the first power supply voltage, and a control electrode of the tenth transistor M10 is connected to the first input terminal A of the AND gate. A second terminal of the first capacitor C1 is connected to the first power supply voltage terminal VDD, and the second terminal of the second capacitor C2 is connected to the first node.

The flip-flop circuit in the seventh example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal-0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep=[7.43V, 7.42V, 7.3V, 7.2V, 7.1V, 7V, 6.8V, 6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the seventh example is described. With continued reference to FIG. 7, a step of generating each clock cycle signal of a clock signal by using the flip-flop circuit in the seventh example includes:

In a first stage, i.e., an initial stage of the clock cycle, the reset signal written into the reset signal terminal HF_Reset is a low-level signal, so that the second transistor M2 is turned on, the ninth transistor M9 is turned off, the first node is reset to −20V, and the third transistor M3 is turned off in this stage.

In a second stage, the reset signal at the reset signal terminal HF_Reset is a high-level signal, so that the second transistor M2 is turned off, the ninth transistor M9 is turned on. The input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the output terminal HF_Output of the AND gate outputs a high-level signal. At the same time, the data voltage control signal written into the data voltage control signal terminal Datastep is written into the control electrode of the fourth transistor M4, and a charging speed for the first node is controlled by controlling a turn-on degree of the fourth transistor M4.

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, which turns on the third transistor M3, so that the second power supply voltage passes through the third transistor M3 to the first input terminal A of the AND gate, which therefore has the second power supply voltage, that is, a voltage at the first input terminal A of the AND gate is a low-level signal, so that the fifth transistor M5 is turned off, the eighth transistor M8 is turned on, and the output terminal HF_Output of the AND gate outputs a low-level signal. Meanwhile, the tenth transistor M10 is turned on, the first node is rapidly charged, and the third transistor M3 is fully turned on.

In a fourth stage, the reset signal at the reset signal terminal HF_Reset is a low-level signal, and the first node is reset to −20V. In this stage, the third transistor M3 is turned off, the first input terminal A of the AND gate retains a low-level signal, and the output terminal HF_Output still outputs the low-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In an eighth example, FIG. 8 is a schematic diagram of a flip-flop circuit in an eighth example of an embodiment of the present disclosure. As shown in FIG. 8, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is directly electrically connected to a first power supply voltage terminal VDD, and a second input terminal B of the AND gate is connected to the first power supply voltage terminal VDD through the input control sub-circuit. The duty ratio adjustment module is connected to the second input terminal B of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The first transistor M1, the third transistor M3, the fifth transistor M5, the sixth transistor M6 and the ninth transistor M9 have the same switching characteristics, the second transistor M2, the fourth transistor M4, the seventh transistor M7, the eighth transistor M8 and the tenth transistor M10 have the same switching characteristics, which are different from those of the first transistor. In this embodiment, as an example, the first transistor M1, the third transistor M3, the fifth transistor M5, the sixth transistor M6 and the ninth transistor M9 are N-type transistors, and the second transistor M2, the fourth transistor M4, the seventh transistor M7, the eighth transistor M8 and the tenth transistor M10 are P-type transistors.

Specifically, with continued reference to FIG. 8, a first electrode of the first transistor M1 is connected to the first power supply voltage terminal VDD, a second electrode of the first transistor M1 is connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the second input terminal B of the AND gate, and a control electrode of the third transistor M3 is connected to the first node. A first electrode of the fourth transistor M4 is connected to the first power supply voltage terminal VDD, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6, a control electrode of the fifth transistor M5 is connected to a control electrode of the eighth transistor M8 as the first input terminal A of the AND gate, which is connected to the first power supply voltage terminal VDD. A second electrode of the sixth transistor M6 is connected to a first electrode of the seventh transistor M7 and a second electrode of the eighth transistor M8 as an output terminal HF_Output of the AND gate, and the control electrode of the sixth transistor M6 is further connected to the first plate of the first capacitor C1. A second electrode of the seventh transistor M7 and a first electrode of the eighth transistor M8 are connected to each other, and connected to the second power supply voltage terminal VSS. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the first power supply voltage, and a control electrode of the tenth transistor M10 is connected to the second input terminal B of the AND gate. A second terminal of the first capacitor C1 is connected to the second power supply voltage terminal VSS, and the second terminal of the second capacitor C2 is connected to the first node.

The flip-flop circuit in the eighth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal=0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep=[7.43V, 7.42V, 7.3V, 7.2V, 7.1V, 7V, 6.8V, 6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the eighth example is described. With continued reference to FIG. 8, a step of generating each clock cycle signal of a clock signal by using the flip-flop circuit in the eighth example includes:

In a first stage, i.e., an initial stage of the clock cycle, the reset signal written into the reset signal terminal HF_Reset is a low-level signal, so that the second transistor M2 is turned on, the ninth transistor M9 is turned off, the first node is reset to −20V, and the third transistor M3 is turned off in this stage.

In a second stage, the reset signal at the reset signal terminal HF_Reset is a high-level signal, so that the second transistor M2 is turned off, and the ninth transistor M9 is turned on. The input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the output terminal HF_Output of the AND gate outputs a high-level signal. At the same time, the data voltage control signal written into the data voltage control signal terminal Datastep is written into the control electrode of the fourth transistor M4, and a charging speed for the first node is controlled by controlling a turn-on degree of the fourth transistor M4.

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, which turns on the third transistor M3, so that the second power supply voltage passes through the third transistor M3 to the first input terminal A of the AND gate, which therefore has the second power supply voltage, that is, a voltage at the first input terminal A of the AND gate is a low-level signal, so that the sixth transistor M6 is turned off, the seventh transistor M7 is turned on, and the output terminal HF_Output of the AND gate outputs a low-level signal. Meanwhile, the tenth transistor M10 is turned on, the first node is rapidly charged, and the third transistor M3 is fully turned on.

In a fourth stage, the reset signal at the reset signal terminal HF_Reset is a low-level signal, and the first node is reset to −20V. In this stage, the third transistor M3 is turned off, the second input terminal B of the AND gate retains a low-level signal, and the output terminal HF_Output still outputs the low-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

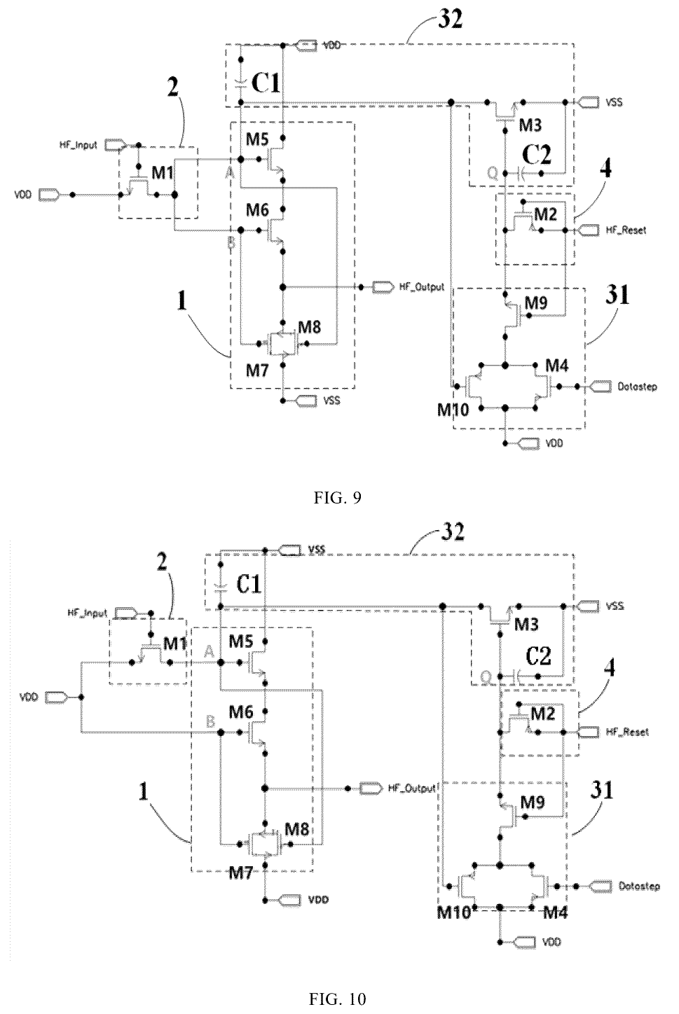

In a ninth example, FIG. 9 is a schematic diagram of a flip-flop circuit in a ninth example of an embodiment of the present disclosure. As shown in FIG. 9, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A and a second input terminal B of the AND gate are electrically connected to a first power supply voltage terminal VDD through the input control sub-circuit.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The first transistor M1, the third transistor M3, the fifth transistor M5, the sixth transistor M6 and the ninth transistor M9 have the same switching characteristics, the second transistor M2, the fourth transistor M4, the seventh transistor M7, the eighth transistor M8 and the tenth transistor M10 have the same switching characteristics, which are different from those of the first transistor. In this embodiment, as an example, the first transistor M1, the third transistor M3, the fifth transistor M5, the sixth transistor M6 and the ninth transistor M9 are N-type transistors, and the second transistor M2, the fourth transistor M4, the seventh transistor M7, the eighth transistor M8 and the tenth transistor M10 are P-type transistors.

Specifically, with continued reference to FIG. 9, a first electrode of the first transistor M1 is connected to the first power supply voltage terminal VDD, a second electrode of the first transistor M1 is connected to a control electrode of the fifth transistor M5 and a control electrode of the eighth transistor M8 as the first input terminal A of the AND gate, the second electrode of the first transistor M1 is also connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the first power supply voltage terminal VDD, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to a control electrode of the seventh transistor M7 and a first plate of the first capacitor C1 as the second input terminal B of the AND gate. A second electrode of the seventh transistor M7 and a first electrode of the eighth transistor M8 are connected to each other, and connected to the second power supply voltage terminal VSS. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the first power supply voltage, and a control electrode of the tenth transistor M10 is connected to the first input terminal A of the AND gate. A second terminal of the first capacitor C1 is connected to the first power supply voltage terminal VDD, and the second terminal of the second capacitor C2 is connected to the first node.

The flip-flop circuit in the ninth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal=0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep=[7.43V, 7.42V, 7.3V, 7.2V, 7.1V, 7V, 6.8V, 6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the ninth example is described. With continued reference to FIG. 9, a step of generating each clock cycle signal of a clock signal by using the flip-flop circuit in the ninth example includes the following stages.

In a first stage, i.e., an initial stage of the clock cycle, the reset signal written into the reset signal terminal HF_Reset is a low-level signal, so that the second transistor M2 is turned on, the ninth transistor M9 is turned off, the first node is reset to −20V, and the third transistor M3 is turned off in this stage.

In a second stage, the reset signal at the reset signal terminal HF_Reset is a high-level signal, so that the second transistor M2 is turned off, the ninth transistor M9 is turned on. The input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the output terminal HF_Output of the AND gate outputs a high-level signal. At the same time, the data voltage control signal written into the data voltage control signal terminal Datastep is written into the control electrode of the fourth transistor M4, and a charging speed for the first node is controlled by controlling a turn-on degree of the fourth transistor M4.

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, which turns on the third transistor M3, so that the second power supply voltage passes through the third transistor M3 to the first input terminal A of the AND gate, which therefore has the second power supply voltage, that is, a voltage at the first input terminal A of the AND gate is a low-level signal, so that the fifth transistor M5 and the sixth transistor M6 are turned off, the seventh transistor M7 and the eighth transistor M8 are turned on, and the output terminal HF_Output of the AND gate outputs a low-level signal. Meanwhile, the tenth transistor M10 is turned on, the first node is rapidly charged, and the third transistor M3 is fully turned on.

In a fourth stage, the reset signal at the reset signal terminal HF_Reset is a low-level signal, and the first node is reset to −20V. In this stage, the third transistor M3 is turned off, the first input terminal A of the AND gate retains a low-level signal, and the output terminal HF_Output still outputs the low-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

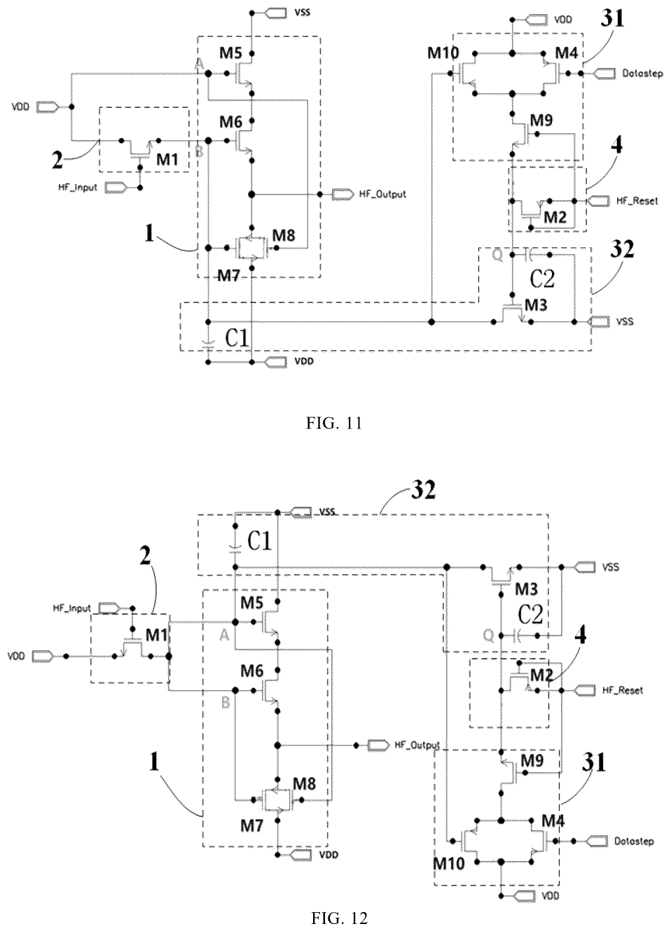

In a tenth example, FIG. 10 is a schematic diagram of a flip-flop circuit in a tenth example of an embodiment of the present disclosure. As shown in FIG. 10, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is electrically connected to a first power supply voltage terminal VDD through the input control sub-circuit, and a second input terminal B of the AND gate is directly connected to the first power supply voltage terminal VDD. The duty ratio adjustment module is connected to the first input terminal A of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The first transistor M1, the third transistor M3, the fifth transistor M5, the sixth transistor M6 and the ninth transistor M9 have the same switching characteristics, the second transistor M2, the fourth transistor M4, the seventh transistor M7, the eighth transistor M8 and the tenth transistor M10 have the same switching characteristics, which are different from those of the first transistor. In this embodiment, as an example, the first transistor M1, the third transistor M3, the fifth transistor M5, the sixth transistor M6 and the ninth transistor M9 are N-type transistors, and the second transistor M2, the fourth transistor M4, the seventh transistor M7, the eighth transistor M8 and the tenth transistor M10 are P-type transistors.

Specifically, with continued reference to FIG. 10, a first electrode of the first transistor M1 is connected to the first power supply voltage terminal VDD, a second electrode of the first transistor M1 is connected to a control electrode of the fifth transistor M5 and a control electrode of the eighth transistor M8 as the first input terminal A of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the first power supply voltage terminal VDD, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to the first power supply voltage terminal VDD and a control electrode of the seventh transistor M7 as the second input terminal B of the AND gate. A second electrode of the seventh transistor M7 and a first electrode of the eighth transistor M8 are connected to each other, and connected to the first power supply voltage terminal VDD. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the first power supply voltage, and a control electrode of the tenth transistor M10 is connected to the first input terminal A of the AND gate. A second terminal of the first capacitor C1 is connected to the second power supply voltage terminal VSS, and the second terminal of the second capacitor C2 is connected to the first node.

The flip-flop circuit in the tenth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal=0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep=[7.43V, 7.42V, 7.3V, 7.2V, 7.1V, 7V, 6.8V, 6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the tenth example is described. With continued reference to FIG. 10, a step of generating each clock cycle signal of a clock signal by using the flip-flop circuit in the tenth example includes the following stages.

In a first stage, i.e., an initial stage of the clock cycle, the reset signal written into the reset signal terminal HF_Reset is a low-level signal, so that the second transistor M2 is turned on, the ninth transistor M9 is turned off, the first node is reset to −20V, and the third transistor M3 is turned off in this stage.

In a second stage, the reset signal at the reset signal terminal HF_Reset is a high-level signal, so that the second transistor M2 is turned off, and the ninth transistor M9 is turned on. The input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the fifth transistor M5 and the sixth transistor M6 are turned on, and the output terminal HF_Output of the AND gate outputs a low-level signal. At the same time, the data voltage control signal written into the data voltage control signal terminal Datastep is written into the control electrode of the fourth transistor M4, and a charging speed for the first node is controlled by controlling a turn-on degree of the fourth transistor M4.

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, which turns on the third transistor M3, so that the second power supply voltage passes through the third transistor M3 to the first input terminal A of the AND gate, which therefore has the second power supply voltage, that is, a voltage at the first input terminal A of the AND gate is a low-level signal. The fifth transistor M5 is turned off, and the eighth transistor M8 is turned on. The output terminal HF_Output of the AND gate outputs a high-level signal. Meanwhile, the tenth transistor M10 is turned on, the first node is rapidly charged, and the third transistor M3 is fully turned on.

In a fourth stage, the reset signal at the reset signal terminal HF_Reset is a low-level signal, and the first node is reset to −20V. In this stage, the third transistor M3 is turned off, the first input terminal A of the AND gate retains a low-level signal, and the output terminal HF_Output still outputs the high-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In an eleventh example, FIG. 11 is a schematic diagram of a flip-flop circuit in an eleventh example of an embodiment of the present disclosure. As shown in FIG. 11, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is directly electrically connected to a first power supply voltage terminal VDD, and a second input terminal B of the AND gate is connected to the first power supply voltage terminal VDD through the input control sub-circuit. The duty ratio adjustment module is connected to the second input terminal B of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The first transistor M1, the third transistor M3, the fifth transistor M5, the sixth transistor M6 and the ninth transistor M9 have the same switching characteristics, the second transistor M2, the fourth transistor M4, the seventh transistor M7, the eighth transistor M8 and the tenth transistor M10 have the same switching characteristics, which are different from those of the first transistor. In this embodiment, as an example, the first transistor M1, the third transistor M3, the fifth transistor M5, the sixth transistor M6 and the ninth transistor M9 are N-type transistors, and the second transistor M2, the fourth transistor M4, the seventh transistor M7, the eighth transistor M8 and the tenth transistor M10 are P-type transistors.

Specifically, with continued reference to FIG. 11, a first electrode of the first transistor M1 is connected to the first power supply voltage terminal VDD, a second electrode of the first transistor M1 is connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the second input terminal B of the AND gate, and a control electrode of the third transistor M3 is connected to the first node. A first electrode of the fourth transistor M4 is connected to the first power supply voltage terminal VDD, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6, a control electrode of the fifth transistor M5 is connected to a control electrode of the eighth transistor M8 as the first input terminal A of the AND gate, which is connected to the first power supply voltage terminal VDD. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is further connected to the first plate of the first capacitor C1. A second electrode of the seventh transistor M7 and a first electrode of the eighth transistor M8 are connected to each other, and connected to the first power supply voltage terminal VDD. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the first power supply voltage, and a control electrode of the tenth transistor M10 is connected to the second input terminal B of the AND gate. A second terminal of the first capacitor C1 is connected to the first power supply voltage terminal VDD, and the second terminal of the second capacitor C2 is connected to the first node.

The flip-flop circuit in the eleventh example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal-0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep-[7.43V, 7.42V, 7.3V, 7.2V, 7.1V, 7V, 6.8V, 6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the eleventh example is described. With continued reference to FIG. 11, a step of generating each clock cycle signal of a clock signal by using the flip-flop circuit in the eleventh example includes the following stages.

In a first stage, i.e., an initial stage of the clock cycle, the reset signal written into the reset signal terminal HF_Reset is a low-level signal, so that the second transistor M2 is turned on, the ninth transistor M9 is turned off, the first node is reset to −20V, and the third transistor M3 is turned off in this stage.

In a second stage, the reset signal at the reset signal terminal HF_Reset is a high-level signal, so that the second transistor M2 is turned off, and the ninth transistor M9 is turned on. The input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the fifth transistor M5 and the sixth transistor M6 are turned on, and the output terminal HF_Output of the AND gate outputs a low-level signal. At the same time, the data voltage control signal written into the data voltage control signal terminal Datastep is written into the control electrode of the fourth transistor M4, and a charging speed for the first node is controlled by controlling a turn-on degree of the fourth transistor M4.

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, which turns on the third transistor M3, so that the second power supply voltage passes through the third transistor M3 to the first input terminal A of the AND gate, which therefore has the second power supply voltage, that is, a voltage at the first input terminal A of the AND gate is a low-level signal. The sixth transistor M6 is turned off, the seventh transistor M7 is turned on, and the output terminal HF_Output of the AND gate outputs a high-level signal. Meanwhile, the tenth transistor M10 is turned on, the first node is rapidly charged, and the third transistor M3 is fully turned on.

In a fourth stage, the reset signal at the reset signal terminal HF_Reset is a low-level signal, and the first node is reset to −20V. In this stage, the third transistor M3 is turned off, the second input terminal B of the AND gate retains a low-level signal, and the output terminal HF_Output outputs the low-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In a twelfth example, FIG. 12 is a schematic diagram of a flip-flop circuit in a twelfth example of an embodiment of the present disclosure. As shown in FIG. 12, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A and a second input terminal B of the AND gate are electrically connected to a first power supply voltage terminal VDD through the input control sub-circuit.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The first transistor M1, the third transistor M3, the fifth transistor M5, the sixth transistor M6 and the ninth transistor M9 have the same switching characteristics, the second transistor M2, the fourth transistor M4, the seventh transistor M7, the eighth transistor M8 and the tenth transistor M10 have the same switching characteristics, which are different from those of the first transistor. In this embodiment, as an example, the first transistor M1, the third transistor M3, the fifth transistor M5, the sixth transistor M6 and the ninth transistor M9 are N-type transistors, and the second transistor M2, the fourth transistor M4, the seventh transistor M7, the eighth transistor M8 and the tenth transistor M10 are P-type transistors.

Specifically, with continued reference to FIG. 12, a first electrode of the first transistor M1 is connected to the first power supply voltage terminal VDD, a second electrode of the first transistor M1 is connected to a control electrode of the fifth transistor M5 and a control electrode of the eighth transistor M8 as the first input terminal A of the AND gate, the second electrode of the first transistor M1 is also connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to a second power supply voltage terminal VSS and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the first power supply voltage terminal VDD, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to a control electrode of the seventh transistor M7 and a first plate of the first capacitor C1 as the second input terminal B of the AND gate. A second electrode of the seventh transistor M7 and a first electrode of the eighth transistor M8 are connected to each other, and connected to the first power supply voltage terminal VDD. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the first power supply voltage, and a control electrode of the tenth transistor M10 is connected to the first input terminal A of the AND gate. A second terminal of the first capacitor C1 is connected to the second power supply voltage terminal VSS, and the second terminal of the second capacitor C2 is connected to the first node.

The flip-flop circuit in the twelfth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a high-level signal/a low-level signal=0.1 μs/99.9 μs; in a timing of a reset signal, a high-level signal is 12V, a low-level signal is −20V, a cycle is H=100 μs, and a duty ratio is a high-level signal/a low-level signal=99.9 μs/0.1 μs; a data voltage control signal is Datastep=[7.43V, 7.42V, 7.3V, 7.2V, 7.1V, 7V, 6.8V, 6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the twelfth example is described. With continued reference to FIG. 12, a step of generating each clock cycle signal of a clock signal by using the flip-flop circuit in the twelfth example includes the following stages.

In a first stage, i.e., an initial stage of the clock cycle, the reset signal written into the reset signal terminal HF_Reset is a low-level signal, so that the second transistor M2 is turned on, the ninth transistor M9 is turned off, the first node is reset to −20V, and the third transistor M3 is turned off in this stage.

In a second stage, the reset signal at the reset signal terminal HF_Reset is a high-level signal, so that the second transistor M2 is turned off, and the ninth transistor M9 is turned on. The input control signal written into the input control signal terminal HF_Input is a high-level signal, so that the first transistor M1 is turned on. At this time, both the first input terminal A and the second input terminal B of the AND gate are provided with the first power supply voltage, that is, a high-level signal, so that the output terminal HF_Output of the AND gate outputs a high-level signal. At the same time, the data voltage control signal written into the data voltage control signal terminal Datastep is written into the control electrode of the fourth transistor M4, and a charging speed for the first node is controlled by controlling a turn-on degree of the fourth transistor M4.

In a third stage, after a duration t elapses, the control electrode of the third transistor M3 is charged by the fourth transistor M4 to a voltage of the potential at the first node minus the second power supply voltage being greater than a threshold voltage of the third transistor M3, that is, VQ-VSS>Vth, which turns on the third transistor M3, so that the second power supply voltage passes through the third transistor M3 to the first input terminal A of the AND gate, which therefore has the second power supply voltage, that is, a voltage at the first input terminal A of the AND gate is a low-level signal. The fifth transistor M5 and the sixth transistor M6 are turned off, and the seventh transistor M7 and the eighth transistor M8 are turned on. The output terminal HF_Output of the AND gate outputs a low-level signal. Meanwhile, the tenth transistor M10 is turned on, the first node is rapidly charged, and the third transistor M3 is fully turned on.

In a fourth stage, the reset signal at the reset signal terminal HF_Reset is a low-level signal, and the first node is reset to −20V. In this stage, the third transistor M3 is turned off, the first input terminal A of the AND gate retains a low-level signal, and the output terminal HF_Output still outputs the low-level signal.

It can be seen that the turn-on degree of the fourth transistor M4 is controlled through the data voltage control signal, to control the charging speed for the first node. The control electrode of the third transistor M3 is charged by the fourth transistor M4 for a duration during which the potential at the first node minus the second power supply voltage is greater than a threshold voltage of the third transistor M3, that is, a duration during which the output terminal HF_Output of the AND gate outputs a high-level signal. The clock signals with different duty ratios may be obtained by adjusting a magnitude of the data voltage control signal.

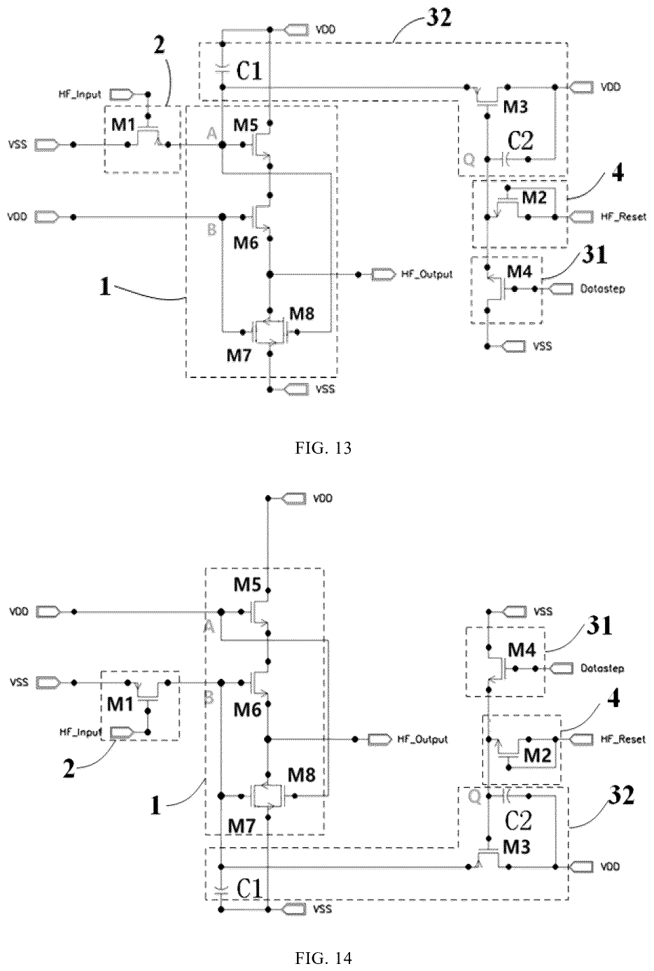

In a thirteenth example, FIG. 13 is a schematic diagram of a flip-flop circuit in a thirteenth example of an embodiment of the present disclosure. As shown in FIG. 13, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is electrically connected to a second power supply voltage terminal VSS through the input control sub-circuit, and a second input terminal B of the AND gate is directly connected to a first power supply voltage terminal VDD. The duty ratio adjustment module is connected to the first input terminal A of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The second transistor M2, the fourth transistor M4, the fifth transistor M5, and the sixth transistor M6 have the same switching characteristics, the first transistor M1, the third transistor M3, the seventh transistor M7, and the eighth transistor M8 have the same switching characteristics, which are different from those of the second transistor. In this embodiment, as an example, the second transistor M2, the fourth transistor M4, the fifth transistor M5, and the sixth transistor M6 are N-type transistors, and the first transistor M1, the third transistor M3, the seventh transistor M7, and the eighth transistor M8 are P-type transistors.

Specifically, with continued reference to FIG. 13, a first electrode of the first transistor M1 is connected to the second power supply voltage terminal VSS, a second electrode of the first transistor M1 is connected to a control electrode of the fifth transistor M5 and a control electrode of the eighth transistor M8 as the first input terminal A of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to the first power supply voltage terminal VDD and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the second power supply voltage terminal VSS, a second electrode of the fourth transistor M4 is connected to the first node, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to the first power supply voltage terminal VDD and a control electrode of the seventh transistor M7 as the second input terminal B of the AND gate. A second electrode of the seventh transistor M7 and a first electrode of the eighth transistor M8 are connected to each other, and connected to the second power supply voltage terminal VSS. A second terminal of the first capacitor C1 is connected to the first power supply voltage terminal VDD, and the second terminal of the second capacitor C2 is connected to the first node.

The flip-flop circuit in the thirteenth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep-[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the thirteenth example is described. With continued reference to FIG. 13, a step of generating each clock cycle signal of a clock signal by using the flip-flop circuit in the thirteenth example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, the input control signal written into the input control signal terminal HF_Input is a low-level signal, so that the first transistor M1 is turned on. At this time, both the first input terminal A and the second input terminal B of the AND gate are provided with the second power supply voltage, so that the fifth transistor M5 is turned off, the eighth transistor M8 is turned on, and the output terminal HF_Output of the AND gate outputs a low-level signal. At the same time, the data voltage control signal written into the data voltage control signal terminal Datastep is written into the control electrode of the fourth transistor M4, and a discharging speed for the first node (i.e., a speed for discharging the first node) is controlled by controlling a turn-on degree of the fourth transistor M4 (i.e., a degree to which the fourth transistor M4 is turned on).

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the first input terminal A of the AND gate, which therefore has the first power supply voltage, that is, a voltage at the first input terminal A of the AND gate is a high-level signal, so that the fifth transistor M5 is turned on. At this time, the output terminal HF_Output of the AND gate outputs a high-level signal.

In a fourth stage, the reset signal at the reset signal terminal HF_Reset is a low-level signal, and the first node is reset to 20V. In this stage, the third transistor M3 is turned off, the first input terminal A of the AND gate retains a low-level signal, and the output terminal HF_Output still outputs the high-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In a fourteenth example, FIG. 14 is a schematic diagram of a flip-flop circuit in a fourteenth example of an embodiment of the present disclosure. As shown in FIG. 14, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is directly connected to a first power supply voltage terminal VDD, and a second input terminal B of the AND gate is connected to a second power supply voltage terminal VSS through the input control sub-circuit. The duty ratio adjustment module is connected to the second input terminal B of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The second transistor M2, the fourth transistor M4, the fifth transistor M5, and the sixth transistor M6 have the same switching characteristics, the first transistor M1, the third transistor M3, the seventh transistor M7, and the eighth transistor M8 have the same switching characteristics, which are different from those of the second transistor. In this embodiment, as an example, the second transistor M2, the fourth transistor M4, the fifth transistor M5, and the sixth transistor M6 are N-type transistors, and the first transistor M1, the third transistor M3, the seventh transistor M7, and the eighth transistor M8 are P-type transistors.

Specifically, with continued reference to FIG. 14, a first electrode of the first transistor M1 is connected to the second power supply voltage terminal VSS, a second electrode of the first transistor M1 is connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to the first power supply voltage terminal VDD and a second terminal of the second capacitor C2, a second electrode of the third transistor M3 is connected to a first terminal of the first capacitor C1 and the second input terminal B of the AND gate, and a control electrode of the third transistor M3 is connected to the first node. A first electrode of the fourth transistor M4 is connected to the second power supply voltage terminal VSS, a second electrode of the fourth transistor M4 is connected to the first node, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6, a control electrode of the fifth transistor M5 is connected to a control electrode of the eighth transistor M8 as the first input terminal A of the AND gate, which is directly connected to the first power supply voltage terminal VDD. A second electrode of the sixth transistor M6 is connected to a first electrode of the seventh transistor M7 and a second electrode of the eighth transistor M8 as an output terminal HF_Output of the AND gate. A second electrode of the seventh transistor M7 and a first electrode of the eighth transistor M8 are connected to each other, and connected to the second power supply voltage terminal VSS. A second terminal of the first capacitor C1 is connected to the second power supply voltage terminal VSS, and the second terminal of the second capacitor C2 is connected to the first node.

The flip-flop circuit in the fourteenth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep=[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the fourteenth example is described. With continued reference to FIG. 14, a step of generating each clock cycle signal of a clock signal by using the flip-flop circuit in the fourteenth example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, the input control signal written into the input control signal terminal HF_Input is a low-level signal, so that the first transistor M1 is turned on. At this time, both the first input terminal A and the second input terminal B of the AND gate are provided with the second power supply voltage, so that the sixth transistor M6 is turned off, the seventh transistor M7 is turned on, and the output terminal HF_Output of the AND gate outputs a low-level signal. At the same time, the data voltage control signal written into the data voltage control signal terminal Datastep is written into the control electrode of the fourth transistor M4, and a discharging speed for the first node is controlled by controlling a turn-on degree of the fourth transistor M4 (i.e., a speed for discharging the first node is controlled by a degree to which the fourth transistor M4 is turned on).

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the second input terminal B of the AND gate, which therefore has the first power supply voltage, that is, a voltage at the second input terminal B of the AND gate is a high-level signal, so that the sixth transistor M6 is turned on. At this time, the output terminal HF_Output of the AND gate outputs a high-level signal.

In a fourth stage, the reset signal at the reset signal terminal HF_Reset is a low-level signal, and the first node is reset to 20V. In this stage, the third transistor M3 is turned off, the first input terminal A of the AND gate retains a low-level signal, and the output terminal HF_Output still outputs the high-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by changing magnitudes of the data voltage control signal.

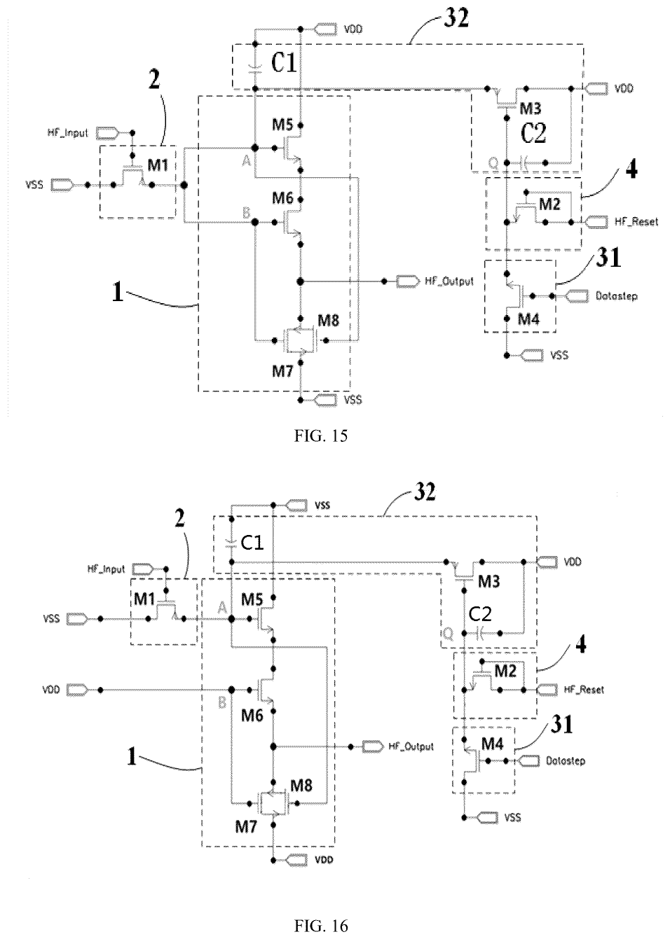

In a fifteenth example, FIG. 15 is a schematic diagram of a flip-flop circuit in a fifteenth example of an embodiment of the present disclosure. As shown in FIG. 15, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A and a second input terminal B of the AND gate are electrically connected to a second power supply voltage terminal VSS through the input control sub-circuit.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The second transistor M2, the fourth transistor M4, the fifth transistor M5, and the sixth transistor M6 have the same switching characteristics, the first transistor M1, the third transistor M3, the seventh transistor M7, and the eighth transistor M8 have the same switching characteristics, which are different from those of the second transistor. In this example, as an example, the second transistor M2, the fourth transistor M4, the fifth transistor M5, and the sixth transistor M6 are N-type transistors, and the first transistor M1, the third transistor M3, the seventh transistor M7, and the eighth transistor M8 are P-type transistors.

Specifically, with continued reference to FIG. 15, a first electrode of the first transistor M1 is connected to the second power supply voltage terminal VSS, a second electrode of the first transistor M1 is connected to a control electrode of the fifth transistor M5 and a control electrode of the eighth transistor M8 as the first input terminal A of the AND gate, and connected to a control electrode of the sixth transistor M6 and a control electrode of the seventh transistor M7 as the second input terminal B of the AND gate. A first electrode and a control electrode of the second transistor M2 are both connected to the reset signal terminal HF_Reset, and a second electrode of the second transistor M2 is connected to the first node. A first electrode of the third transistor M3 is connected to a first power supply voltage terminal VDD and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the second power supply voltage terminal VSS, a second electrode of the fourth transistor M4 is connected to the first node, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to a control electrode of the seventh transistor M7 and a first plate of the first capacitor C1 as the second input terminal B of the AND gate. A second electrode of the seventh transistor M7 and a first electrode of the eighth transistor M8 are connected to each other, and connected to the second power supply voltage terminal VSS. A second terminal of the first capacitor C1 is connected to the first power supply voltage terminal VDD, and the second terminal of the second capacitor C2 is connected to the first node.

The flip-flop circuit in the fifteenth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep=[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the fifteenth example is described. With continued reference to FIG. 15, a step of generating each clock cycle signal of a clock signal by using the flip-flop circuit in the fifteenth example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, the input control signal written into the input control signal terminal HF_Input is a low-level signal, so that the first transistor M1 is turned on. At this time, both the first input terminal A and the second input terminal B of the AND gate are provided with the second power supply voltage, so that the fifth transistor M5 and the sixth transistor M6 are turned off, the seventh transistor M7 and the eighth transistor M8 are turned on, and the output terminal HF_Output of the AND gate outputs a low-level signal. At the same time, the data voltage control signal written into the data voltage control signal terminal Datastep is written into the control electrode of the fourth transistor M4, and a discharging speed for the first node is controlled by controlling a turn-on degree of the fourth transistor M4.

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the first input terminal A of the AND gate, which therefore has the first power supply voltage, that is, a voltage at the first input terminal A of the AND gate is a high-level signal, so that the fifth transistor M5 is turned on. At this time, the output terminal HF_Output of the AND gate outputs a high-level signal.

In a fourth stage, the reset signal at the reset signal terminal HF_Reset is a low-level signal, and the first node is reset to 20V. In this stage, the third transistor M3 is turned off, the first input terminal A of the AND gate retains a low-level signal, and the output terminal HF_Output still outputs the high-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In a sixteenth example, FIG. 16 is a schematic diagram of a flip-flop circuit in a sixteenth example of an embodiment of the present disclosure. As shown in FIG. 16, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is electrically connected to a second power supply voltage terminal VSS through the input control sub-circuit, and a second input terminal B of the AND gate is directly connected to a first power supply voltage terminal VDD. The duty ratio adjustment module is connected to the first input terminal A of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The second transistor M2, the fourth transistor M4, the fifth transistor M5, and the sixth transistor M6 have the same switching characteristics, the first transistor M1, the third transistor M3, the seventh transistor M7, and the eighth transistor M8 have the same switching characteristics, which are different from those of the second transistor. In this embodiment, as an example, the second transistor M2, the fourth transistor M4, the fifth transistor M5, and the sixth transistor M6 are N-type transistors, and the first transistor M1, the third transistor M3, the seventh transistor M7, and the eighth transistor M8 are P-type transistors.

Specifically, with continued reference to FIG. 16, a first electrode of the first transistor M1 is connected to the second power supply voltage terminal VSS, a second electrode of the first transistor M1 is connected to a control electrode of the fifth transistor M5 and a control electrode of the eighth transistor M8 as the first input terminal A of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to the first power supply voltage terminal VDD and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the second power supply voltage terminal VSS, a second electrode of the fourth transistor M4 is connected to the first node, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to the first power supply voltage terminal VDD and a control electrode of the seventh transistor M7 as the second input terminal B of the AND gate. A second electrode of the seventh transistor M7 and a first electrode of the eighth transistor M8 are connected to each other, and connected to the first power supply voltage terminal VDD. A second terminal of the first capacitor C1 is connected to the second power supply voltage terminal VSS, and the second terminal of the second capacitor C2 is connected to the first node.

The flip-flop circuit in the sixteenth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep=[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the sixteenth example is described. With continued reference to FIG. 16, a step of generating each clock cycle signal of a clock signal by using the flip-flop circuit in the sixteenth example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, the input control signal written into the input control signal terminal HF_Input is a low-level signal, so that the first transistor M1 is turned on. At this time, the first input terminal A of the AND gate is provided with the second power supply voltage and the second input terminal B of the AND gate is provided with the first power supply voltage, so that the fifth transistor M5 is turned off, the eighth transistor M8 is turned on, and the output terminal HF_Output of the AND gate outputs a high-level signal. At the same time, the data voltage control signal written into the data voltage control signal terminal Datastep is written into the control electrode of the fourth transistor M4, and a discharging speed for the first node is controlled by controlling a turn-on degree of the fourth transistor M4 (i.e., a speed for discharging the first node is controlled by controlling a degree to which the fourth transistor M4 is turned on).

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the first input terminal A of the AND gate, which therefore has the first power supply voltage, that is, a voltage at the first input terminal A of the AND gate is a high-level signal, so that the fifth transistor M5 is turned on. At this time, the output terminal HF_Output of the AND gate outputs a low-level signal.

In a fourth stage, the reset signal at the reset signal terminal HF_Reset is a low-level signal, and the first node is reset to 20V. In this stage, the third transistor M3 is turned off, the first input terminal A of the AND gate retains a low-level signal, so that the eighth transistor M8 is turned on. The output terminal HF_Output outputs the high-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by adjusting a magnitude of the data voltage control signal.

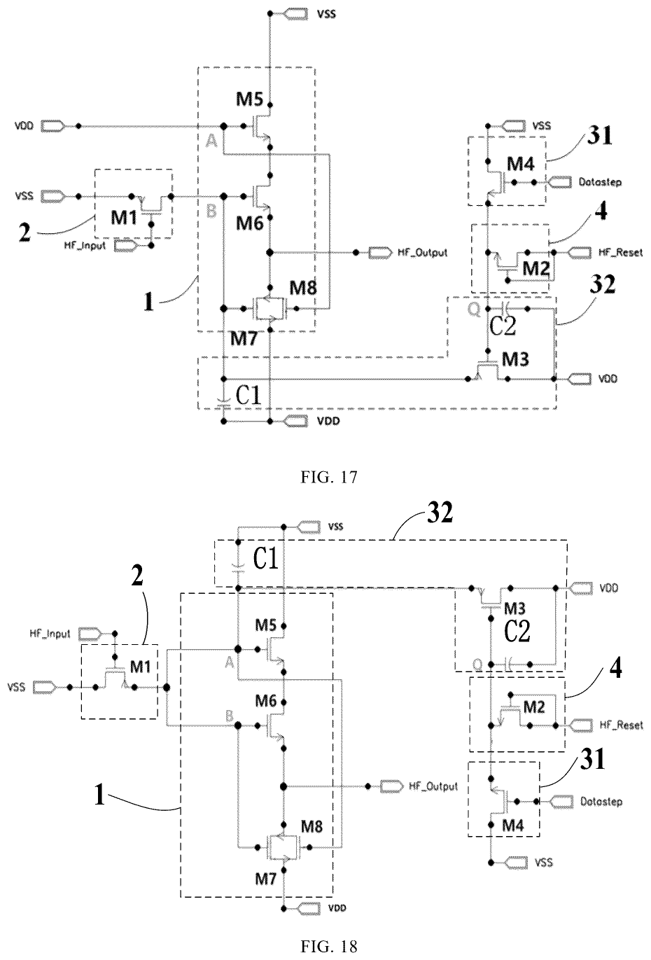

In a seventeenth example, FIG. 17 is a schematic diagram of a flip-flop circuit in a seventeenth example of an embodiment of the present disclosure. As shown in FIG. 17, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is directly connected to a first power supply voltage terminal VDD, and a second input terminal B of the AND gate is connected to a second power supply voltage terminal VSS through the input control sub-circuit. The duty ratio adjustment module is connected to the second input terminal B of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The second transistor M2, the fourth transistor M4, the fifth transistor M5, and the sixth transistor M6 have the same switching characteristics, the first transistor M1, the third transistor M3, the seventh transistor M7, and the eighth transistor M8 have the same switching characteristics, which are different from those of the second transistor. In this embodiment, as an example, the second transistor M2, the fourth transistor M4, the fifth transistor M5, and the sixth transistor M6 are N-type transistors, and the first transistor M1, the third transistor M3, the seventh transistor M7, and the eighth transistor M8 are P-type transistors.

Specifically, with continued reference to FIG. 17, a first electrode of the first transistor M1 is connected to the second power supply voltage terminal VSS, a second electrode of the first transistor M1 is connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to the first power supply voltage terminal VDD and a second terminal of the second capacitor C2, a second electrode of the third transistor M3 is connected to a first terminal of the first capacitor C1 and the second input terminal B of the AND gate, and a control electrode of the third transistor M3 is connected to the first node. A first electrode of the fourth transistor M4 is connected to the second power supply voltage terminal VSS, a second electrode of the fourth transistor M4 is connected to the first node, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6, a control electrode of the fifth transistor M5 is connected to a control electrode of the eighth transistor M8 as the first input terminal A of the AND gate, which is directly connected to the first power supply voltage terminal VDD. A second electrode of the sixth transistor M6 is connected to a first electrode of the seventh transistor M7 and a second electrode of the eighth transistor M8 as an output terminal HF_Output of the AND gate. A second electrode of the seventh transistor M7 and a first electrode of the eighth transistor M8 are connected to each other, and connected to the first power supply voltage terminal VDD. A second terminal of the first capacitor C1 is connected to the first power supply voltage terminal VDD, and the second terminal of the second capacitor C2 is connected to the first node.

The flip-flop circuit in the seventeenth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep=[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the seventeenth example is described. With continued reference to FIG. 17, a step of generating each clock cycle signal of a clock signal by using the flip-flop circuit in the seventeenth example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, the input control signal written into the input control signal terminal HF_Input is a low-level signal, so that the first transistor M1 is turned on. At this time, the first input terminal A of the AND gate is provided with the first power supply voltage and the second input terminal B of the AND gate is provided with the second power supply voltage, so that the sixth transistor M6 is turned off, the seventh transistor M7 is turned on, and the output terminal HF_Output of the AND gate outputs a high-level signal. At the same time, the data voltage control signal written into the data voltage control signal terminal Datastep is written into the control electrode of the fourth transistor M4, and a discharging speed for the first node is controlled by controlling a turn-on degree of the fourth transistor M4.

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the second input terminal B of the AND gate, which therefore has the first power supply voltage, that is, a voltage at the second input terminal B of the AND gate is a high-level signal, so that the sixth transistor M6 is turned on. At this time, the output terminal HF_Output of the AND gate outputs a low-level signal.

In a fourth stage, the reset signal at the reset signal terminal HF_Reset is a low-level signal, and the first node is reset to 20V. In this stage, the third transistor M3 is turned off, the second input terminal B of the AND gate retains a low-level signal, so that the seventh transistor M7 is turned on. The output terminal HF_Output outputs the high-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In an eighteenth example, FIG. 18 is a schematic diagram of a flip-flop circuit in an eighteenth example of an embodiment of the present disclosure. As shown in FIG. 18, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A and a second input terminal B of the AND gate are electrically connected to a second power supply voltage terminal VSS through the input control sub-circuit.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4. The AND gate includes a fifth transistor M5, a sixth transistor M6, a seventh transistor M7, and an eighth transistor M8. The second transistor M2, the fourth transistor M4, the fifth transistor M5, and the sixth transistor M6 have the same switching characteristics, the first transistor M1, the third transistor M3, the seventh transistor M7, and the eighth transistor M8 have the same switching characteristics, which are different from those of the second transistor. In this embodiment, as an example, the second transistor M2, the fourth transistor M4, the fifth transistor M5, and the sixth transistor M6 are N-type transistors, and the first transistor M1, the third transistor M3, the seventh transistor M7, and the eighth transistor M8 are P-type transistors.

Specifically, with continued reference to FIG. 18, a first electrode of the first transistor M1 is connected to the second power supply voltage terminal VSS, a second electrode of the first transistor M1 is connected to a control electrode of the fifth transistor M5 and a control electrode of the eighth transistor M8 as the first input terminal A of the AND gate, and connected to a control electrode of the sixth transistor M6 and a control electrode of the seventh transistor M7 as the second input terminal B of the AND gate. A first electrode and a control electrode of the second transistor M2 are both connected to the reset signal terminal HF_Reset, and a second electrode of the second transistor M2 is connected to the first node. A first electrode of the third transistor M3 is connected to a first power supply voltage terminal VDD and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the second power supply voltage terminal VSS, a second electrode of the fourth transistor M4 is connected to the first node, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to a control electrode of the seventh transistor M7 as the second input terminal B of the AND gate. A second electrode of the seventh transistor M7 and a first electrode of the eighth transistor M8 are connected to each other, and connected to the first power supply voltage terminal VDD. A second terminal of the first capacitor C1 is connected to the second power supply voltage terminal VSS, and the second terminal of the second capacitor C2 is connected to the first node.

The flip-flop circuit in the eighteenth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep=[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the eighteenth example is described. With continued reference to FIG. 18, a step of generating each clock cycle signal of a clock signal by using the flip-flop circuit in the eighteenth example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, the input control signal written into the input control signal terminal HF_Input is a low-level signal, so that the first transistor M1 is turned on. At this time, both the first input terminal A and the second input terminal B of the AND gate are provided with the second power supply voltage, so that the fifth transistor M5 and the sixth transistor M6 are turned off, the seventh transistor M7 and the eighth transistor M8 are turned on, and the output terminal HF_Output of the AND gate outputs a high-level signal. At the same time, the data voltage control signal written into the data voltage control signal terminal Datastep is written into the control electrode of the fourth transistor M4, and a discharging speed for the first node is controlled by controlling a turn-on degree of the fourth transistor M4.

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the first input terminal A of the AND gate, which therefore has the first power supply voltage, that is, a voltage at the first input terminal A of the AND gate is a high-level signal, so that the fifth transistor M5 is turned on. At this time, the output terminal HF_Output of the AND gate outputs a low-level signal.

In a fourth stage, the reset signal at the reset signal terminal HF_Reset is a low-level signal, and the first node is reset to 20V. In this stage, the third transistor M3 is turned off, the first input terminal A of the AND gate retains a low-level signal, so that the eighth transistor M8 is turned on. The output terminal HF_Output outputs the high-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by adjusting a magnitude of the data voltage control signal.

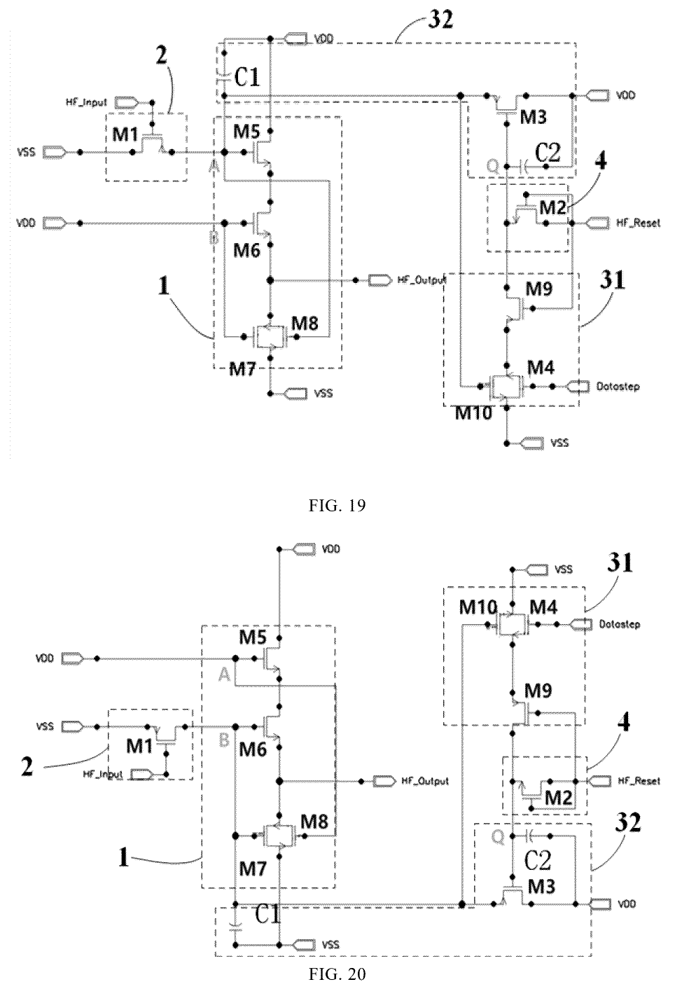

In a nineteenth example, FIG. 19 is a schematic diagram of a flip-flop circuit in a nineteenth example of an embodiment of the present disclosure. As shown in FIG. 19, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is electrically connected to a second power supply voltage terminal VSS through the input control sub-circuit, and a second input terminal B of the AND gate is directly connected to a first power supply voltage terminal VDD. The duty ratio adjustment module is connected to the first input terminal A of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The second transistor M2, the fourth transistor M4, the fifth transistor M5, the sixth transistor M6 and the tenth transistor M10 have the same switching characteristics, the first transistor M1, the third transistor M3, the seventh transistor M7, the eighth transistor M8 and the ninth transistor M9 have the same switching characteristics, which are different from those of the second transistor. In this embodiment, as an example, the second transistor M2, the fourth transistor M4, the fifth transistor M5, the sixth transistor M6 and the tenth transistor M10 are N-type transistors, and the first transistor M1, the third transistor M3, the seventh transistor M7, the eighth transistor M8 and the ninth transistor M9 are P-type transistors.

Specifically, with continued reference to FIG. 19, a first electrode of the first transistor M1 is connected to the second power supply voltage terminal VSS, a second electrode of the first transistor M1 is connected to a control electrode of the fifth transistor M5 and a control electrode of the eighth transistor M8 as the first input terminal A of the AND gate, and a control electrode of the first transistor M is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to the first power supply voltage terminal VDD and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the second power supply voltage terminal VSS, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to a control electrode of the seventh transistor M7 as the second input terminal B of the AND gate. A second electrode of the seventh transistor M7 and a first electrode of the eighth transistor M8 are connected to each other, and connected to the second power supply voltage terminal VSS. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the second power supply voltage, and a control electrode of the tenth transistor M10 is connected to the first input terminal A of the AND gate. A second terminal of the first capacitor C1 is connected to the first power supply voltage terminal VDD, and the second terminal of the second capacitor C2 is connected to the first node.

The flip-flop circuit in the nineteenth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep=[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the nineteenth example is described. With continued reference to FIG. 19, a step of generating each clock cycle signal of a clock signal by using the flip-flop circuit in the nineteenth example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, so that the second transistor M2 is turned off, the ninth transistor M9 is turned on. The input control signal written into the input control signal terminal HF_Input is a low-level signal, so that the first transistor M1 is turned on. At this time, the first input terminal A of the AND gate is provided with the second power supply voltage and the second input terminal B of the AND gate is provided with the first power supply voltage, so that the fifth transistor M5 is turned off, the eighth transistor M8 is turned on, and the output terminal HF_Output of the AND gate outputs a low-level signal. At the same time, the data voltage control signal written into the data voltage control signal terminal Datastep is written into the control electrode of the fourth transistor M4, and a discharging speed for the first node is controlled by controlling a turn-on degree of the fourth transistor M4.

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the first input terminal A of the AND gate, which therefore has the first power supply voltage, that is, a voltage at the first input terminal A of the AND gate is a high-level signal, so that the fifth transistor M5 is turned on. At this time, the output terminal HF_Output of the AND gate outputs a high-level signal.

In a fourth stage, the reset signal at the reset signal terminal HF_Reset is a low-level signal, and the first node is reset to 20V. In this stage, the third transistor M3 is turned off, the first input terminal A of the AND gate retains a high-level signal, so that the fifth transistor M5 is turned on. The output terminal HF_Output still outputs the high-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In a twentieth example, FIG. 20 is a schematic diagram of a flip-flop circuit in a twentieth example of an embodiment of the present disclosure. As shown in FIG. 20, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is directly connected to a first power supply voltage terminal VDD, and a second input terminal B of the AND gate is connected to a second power supply voltage terminal VSS through the input control sub-circuit. The duty ratio adjustment module is connected to the second input terminal B of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The second transistor M2, the fourth transistor M4, the fifth transistor M5, the sixth transistor M6 and the tenth transistor M10 have the same switching characteristics, the first transistor M1, the third transistor M3, the seventh transistor M7, the eighth transistor M8 and the ninth transistor M9 have the same switching characteristics, which are different from those of the second transistor. In this embodiment, as an example, the second transistor M2, the fourth transistor M4, the fifth transistor M5, the sixth transistor M6 and the tenth transistor M10 are N-type transistors, and the first transistor M1, the third transistor M3, the seventh transistor M7, the eighth transistor M8 and the ninth transistor M9 are P-type transistors.

Specifically, with continued reference to FIG. 20, a first electrode of the first transistor M1 is connected to the second power supply voltage terminal VSS, a second electrode of the first transistor M1 is connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to the first power supply voltage terminal VDD and a second terminal of the second capacitor C2, a second electrode of the third transistor M3 is connected to a first terminal of the first capacitor C1 and the second input terminal B of the AND gate, and a control electrode of the third transistor M3 is connected to the first node. A first electrode of the fourth transistor M4 is connected to the second power supply voltage terminal VSS, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6, a control electrode of the fifth transistor M5 is connected to a control electrode of the eighth transistor M8 as the first input terminal A of the AND gate, which is directly connected to the first power supply voltage terminal VDD. A second electrode of the sixth transistor M6 is connected to a first electrode of the seventh transistor M7 and a second electrode of the eighth transistor M8 as an output terminal HF_Output of the AND gate. A second electrode of the seventh transistor M7 and a first electrode of the eighth transistor M8 are connected to each other, and connected to the second power supply voltage terminal VSS. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the second power supply voltage, and a control electrode of the tenth transistor M10 is connected to the second input terminal B of the AND gate. A second terminal of the first capacitor C1 is connected to the second power supply voltage terminal VSS, and the second terminal of the second capacitor C2 is connected to the first node.

The flip-flop circuit in the twentieth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep=[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the twentieth example is described. With continued reference to FIG. 20, a step of generating each clock cycle signal of a clock signal by using the flip-flop circuit in the twentieth example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, so that the second transistor M2 is turned off, the ninth transistor M9 is turned on. The input control signal written into the input control signal terminal HF_Input is a low-level signal, so that the first transistor M1 is turned on. At this time, the first input terminal A of the AND gate is provided with the first power supply voltage and the second input terminal B of the AND gate is provided with the second power supply voltage, so that the sixth transistor M6 is turned off, the seventh transistor M7 is turned on, and the output terminal HF_Output of the AND gate outputs a low-level signal. At the same time, the data voltage control signal written into the data voltage control signal terminal Datastep is written into the control electrode of the fourth transistor M4, and a discharging speed for the first node is controlled by controlling a turn-on degree of the fourth transistor M4.

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the first input terminal A of the AND gate, which therefore has the first power supply voltage, that is, a voltage at the first input terminal A of the AND gate is a high-level signal, so that the fifth transistor M5 is turned on. At this time, the output terminal HF_Output of the AND gate outputs a high-level signal.

In a fourth stage, the reset signal at the reset signal terminal HF_Reset is a low-level signal, and the first node is reset to 20V. In this stage, the third transistor M3 is turned off, the second input terminal B of the AND gate retains a high-level signal, so that the sixth transistor M6 is turned on. The output terminal HF_Output still outputs the high-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by adjusting a magnitude of the data voltage control signal.

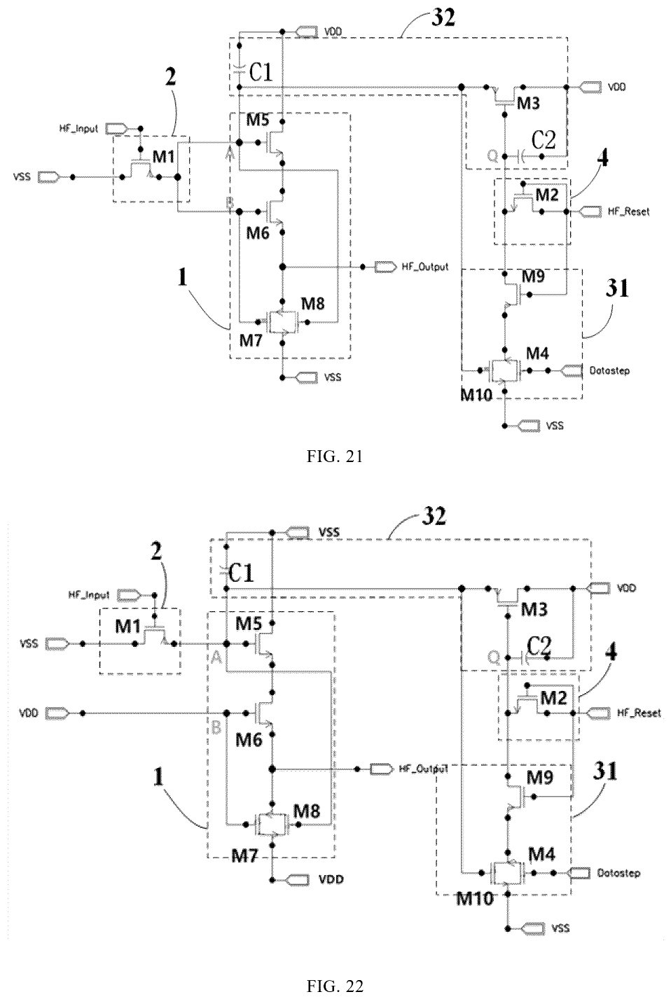

In a twenty-first example, FIG. 21 is a schematic diagram of a flip-flop circuit in a twenty-first example of an embodiment of the present disclosure. As shown in FIG. 21, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A and a second input terminal B of the AND gate are electrically connected to a second power supply voltage terminal VSS through the input control sub-circuit.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The second transistor M2, the fourth transistor M4, the fifth transistor M5, the sixth transistor M6 and the tenth transistor M10 have the same switching characteristics, the first transistor M1, the third transistor M3, the seventh transistor M7, the eighth transistor M8 and the ninth transistor M9 have the same switching characteristics, which are different from those of the second transistor. In this embodiment, as an example, the second transistor M2, the fourth transistor M4, the fifth transistor M5, the sixth transistor M6 and the tenth transistor M10 are N-type transistors, and the first transistor M1, the third transistor M3, the seventh transistor M7, the eighth transistor M8 and the ninth transistor M9 are P-type transistors.

Specifically, with continued reference to FIG. 21, a first electrode of the first transistor M1 is connected to the second power supply voltage terminal VSS, a second electrode of the first transistor M1 is connected to a control electrode of the fifth transistor M5 and a control electrode of the eighth transistor M8 as the first input terminal A of the AND gate, and connected to a control electrode of the sixth transistor M6 and a control electrode of the seventh transistor M7 as the second input terminal B of the AND gate. A first electrode and a control electrode of the second transistor M2 are both connected to the reset signal terminal HF_Reset, and a second electrode of the second transistor M2 is connected to the first node. A first electrode of the third transistor M3 is connected to a first power supply voltage terminal VDD and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the second power supply voltage terminal VSS, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the first power supply voltage terminal VDD, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to a control electrode of the seventh transistor M7 as the second input terminal B of the AND gate. A second electrode of the seventh transistor M7 and a first electrode of the eighth transistor M8 are connected to each other, and connected to the second power supply voltage terminal VSS. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the second power supply voltage, and a control electrode of the tenth transistor M10 is connected to the first input terminal A of the AND gate. A second terminal of the first capacitor C1 is connected to the first power supply voltage terminal VDD, and the second terminal of the second capacitor C2 is connected to the first node.

The flip-flop circuit in the twenty-first example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep=[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the twenty-first example is described. With continued reference to FIG. 21, a step of generating each clock cycle signal of a clock signal by using the flip-flop circuit in the twenty-first example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, so that the second transistor M2 is turned off, the ninth transistor M9 is turned on. The input control signal written into the input control signal terminal HF_Input is a low-level signal, so that the first transistor M1 is turned on. At this time, both the first input terminal A and the second input terminal B of the AND gate are provided with the second power supply voltage, so that the fifth transistor M5 and the sixth transistor M6 are turned off, the seventh transistor M7 and the eighth transistor M8 are turned on, and the output terminal HF_Output of the AND gate outputs a low-level signal. At the same time, the data voltage control signal written into the data voltage control signal terminal Datastep is written into the control electrode of the fourth transistor M4, and a discharging speed for the first node is controlled by controlling a turn-on degree of the fourth transistor M4 (i.e., a speed for discharging the first node is controlled by controlling a degree to which the fourth transistor M4 is turned on).

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the first input terminal A of the AND gate, which therefore has the first power supply voltage, that is, a voltage at the first input terminal A of the AND gate is a high-level signal, so that the fifth transistor M5 is turned on. At this time, the output terminal HF_Output of the AND gate outputs a high-level signal.

In a fourth stage, the reset signal at the reset signal terminal HF_Reset is a low-level signal, and the first node is reset to 20V. In this stage, the third transistor M3 is turned off, the first input terminal A of the AND gate retains a high-level signal, so that the fifth transistor M5 is turned on. The output terminal HF_Output still outputs the high-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In a twenty-second example, FIG. 22 is a schematic diagram of a flip-flop circuit in a twenty-second example of an embodiment of the present disclosure. As shown in FIG. 22, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is electrically connected to a second power supply voltage terminal VSS through the input control sub-circuit, and a second input terminal B of the AND gate is directly connected to a first power supply voltage terminal VDD. The duty ratio adjustment module is connected to the first input terminal A of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The second transistor M2, the fourth transistor M4, the fifth transistor M5, the sixth transistor M6 and the tenth transistor M10 have the same switching characteristics, the first transistor M1, the third transistor M3, the seventh transistor M7, the eighth transistor M8 and the ninth transistor M9 have the same switching characteristics, which are different from those of the second transistor M2. In this embodiment, as an example, the second transistor M2, the fourth transistor M4, the fifth transistor M5, the sixth transistor M6 and the tenth transistor M10 are N-type transistors, and the first transistor M1, the third transistor M3, the seventh transistor M7, the eighth transistor M8 and the ninth transistor M9 are P-type transistors.

Specifically, with continued reference to FIG. 22, a first electrode of the first transistor M1 is connected to the second power supply voltage terminal VSS, a second electrode of the first transistor M1 is connected to a control electrode of the fifth transistor M5 and a control electrode of the eighth transistor M8 as the first input terminal A of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to the first power supply voltage terminal VDD and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the second power supply voltage terminal VSS, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to the first power supply voltage terminal VDD and a control electrode of the seventh transistor M7 as the second input terminal B of the AND gate. A second electrode of the seventh transistor M7 and a first electrode of the eighth transistor M8 are connected to each other, and connected to the first power supply voltage terminal VDD. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the second power supply voltage, and a control electrode of the tenth transistor M10 is connected to the first input terminal A of the AND gate. A second terminal of the first capacitor C1 is connected to the second power supply voltage terminal VSS, and the second terminal of the second capacitor C2 is connected to the first node.

The flip-flop circuit in the twenty-second example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep=[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the twenty-second example is described. With continued reference to FIG. 22, a step of generating each clock cycle signal of a clock signal by using the flip-flop circuit in the twenty-second example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, so that the second transistor M2 is turned off, the ninth transistor M9 is turned on. The input control signal written into the input control signal terminal HF_Input is a low-level signal, so that the first transistor M1 is turned on. At this time, the first input terminal A of the AND gate is provided with the second power supply voltage and the second input terminal B of the AND gate is provided with the first power supply voltage, so that the fifth transistor M5 is turned off, the eighth transistor M8 is turned on, and the output terminal HF_Output of the AND gate outputs a high-level signal. At the same time, the data voltage control signal written into the data voltage control signal terminal Datastep is written into the control electrode of the fourth transistor M4, and a discharging speed for the first node is controlled by controlling a turn-on degree of the fourth transistor M4.

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the first input terminal A of the AND gate, which therefore has the first power supply voltage, that is, a voltage at the first input terminal A of the AND gate is a high-level signal, so that the fifth transistor M5 is turned on. At this time, the output terminal HF_Output of the AND gate outputs a low-level signal.

In a fourth stage, the reset signal at the reset signal terminal HF_Reset is a low-level signal, and the first node is reset to 20V. In this stage, the third transistor M3 is turned off, the first input terminal A of the AND gate retains a high-level signal, so that the fifth transistor M5 is turned on. The output terminal HF_Output outputs the high-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by adjusting a magnitude of the data voltage control signal.

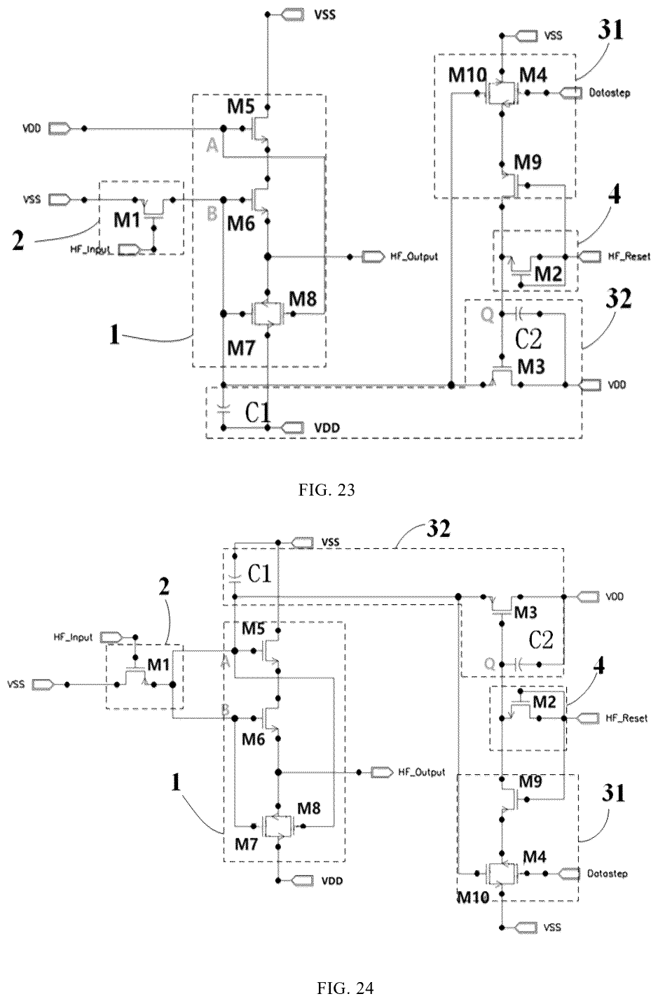

In a twenty-third example, FIG. 23 is a schematic diagram of a flip-flop circuit in a twenty-third example of an embodiment of the present disclosure. As shown in FIG. 23, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A of the AND gate is directly connected to a first power supply voltage terminal VDD, and a second input terminal B of the AND gate is connected to a second power supply voltage terminal VSS through the input control sub-circuit. The duty ratio adjustment module is connected to the second input terminal B of the AND gate.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The second transistor M2, the fourth transistor M4, the fifth transistor M5, the sixth transistor M6 and the tenth transistor M10 have the same switching characteristics, the first transistor M1, the third transistor M3, the seventh transistor M7, the eighth transistor M8 and the ninth transistor M9 have the same switching characteristics, which are different from those of the second transistor. In this embodiment, as an example, the second transistor M2, the fourth transistor M4, the fifth transistor M5, the sixth transistor M6 and the tenth transistor M10 are N-type transistors, and the first transistor M1, the third transistor M3, the seventh transistor M7, the eighth transistor M8 and the ninth transistor M9 are P-type transistors.

Specifically, with continued reference to FIG. 23, a first electrode of the first transistor M1 is connected to the second power supply voltage terminal VSS, a second electrode of the first transistor M1 is connected to a control electrode of the sixth transistor M6 and a control electrode of the seventh transistor M7 as the second input terminal B of the AND gate, and a control electrode of the first transistor M1 is connected to the input control signal terminal HF_Input. A first electrode and a control electrode of the second transistor M2 are both connected to the reset signal terminal HF_Reset, and a second electrode of the second transistor M2 is connected to the first node. A first electrode of the third transistor M3 is connected to the first power supply voltage terminal VDD and a second terminal of the second capacitor C2, a second electrode of the third transistor M3 is connected to a first terminal of the first capacitor C1 and the second input terminal B of the AND gate, and a control electrode of the third transistor M3 is connected to the first node. A first electrode of the fourth transistor M4 is connected to the second power supply voltage terminal VSS, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6, a control electrode of the fifth transistor M5 is connected to a control electrode of the eighth transistor M8 as the first input terminal A of the AND gate, which is directly connected to the first power supply voltage terminal VDD. A second electrode of the sixth transistor M6 is connected to a first electrode of the seventh transistor M7 and a second electrode of the eighth transistor M8 as an output terminal HF_Output of the AND gate. A second electrode of the seventh transistor M7 and a first electrode of the eighth transistor M8 are connected to each other, and connected to the first power supply voltage terminal VDD. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the second power supply voltage, and a control electrode of the tenth transistor M10 is connected to the second input terminal B of the AND gate. A second terminal of the first capacitor C1 is connected to the first power supply voltage terminal VDD, and the second terminal of the second capacitor C2 is connected to the first node.

The flip-flop circuit in the twenty-third example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep-[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the twenty-third example is described. With continued reference to FIG. 23, a step of generating each clock cycle signal of a clock signal by using the flip-flop circuit in the twenty-third example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, so that the second transistor M2 is turned off, the ninth transistor M9 is turned on. The input control signal written into the input control signal terminal HF_Input is a low-level signal, so that the first transistor M1 is turned on. At this time, the first input terminal A of the AND gate is provided with the first power supply voltage and the second input terminal B of the AND gate is provided with the second power supply voltage, so that the sixth transistor M6 is turned off, the seventh transistor M7 is turned on, and the output terminal HF_Output of the AND gate outputs a high-level signal. At the same time, the data voltage control signal written into the data voltage control signal terminal Datastep is written into the control electrode of the fourth transistor M4, and a discharging speed for the first node is controlled by controlling a turn-on degree of the fourth transistor M4.

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the second input terminal B of the AND gate, which therefore has the first power supply voltage, that is, a voltage at the second input terminal B of the AND gate is a high-level signal, so that the sixth transistor M6 is turned on. At this time, the output terminal HF_Output of the AND gate outputs a low-level signal.

In a fourth stage, the reset signal at the reset signal terminal HF_Reset is a low-level signal, and the first node is reset to 20V. In this stage, the third transistor M3 is turned off, the second input terminal B of the AND gate retains a high-level signal, so that the sixth transistor M6 is turned on. The output terminal HF_Output still outputs the low-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by adjusting a magnitude of the data voltage control signal.

In a twenty-fourth example, FIG. 24 is a schematic diagram of a flip-flop circuit in a twenty-fourth example of an embodiment of the present disclosure. As shown in FIG. 24, the flip-flop circuit includes an AND gate, an input control sub-circuit, a duty ratio adjustment sub-circuit, and a reset sub-circuit. The duty cycle adjustment sub-circuit includes a control module and a duty ratio adjustment module, a connection node between the control module and the duty cycle adjustment sub-circuit is a first node, and the reset sub-circuit is connected to the first node. A first input terminal A and a second input terminal B of the AND gate are electrically connected to a second power supply voltage terminal VSS through the input control sub-circuit.

The input control sub-circuit includes a first transistor M1. The reset sub-circuit includes a second transistor M2. The duty cycle adjustment module includes a third transistor M3, a first capacitor C1, and a second capacitor C2. The control module includes a fourth transistor M4, a ninth transistor M9, and a tenth transistor M10. The AND gate includes a fifth transistor M5, a sixth transistor M6, a seventh transistor M7, and an eighth transistor M8. The second transistor M2, the fourth transistor M4, the fifth transistor M5, the sixth transistor M6 and the tenth transistor M10 have the same switching characteristics, the first transistor M1, the third transistor M3, the seventh transistor M7, the eighth transistor M8 and the ninth transistor M9 have the same switching characteristics, which are different from those of the second transistor M2. In this embodiment, as an example, the second transistor M2, the fourth transistor M4, the fifth transistor M5, the sixth transistor M6 and the tenth transistor M10 are N-type transistors, and the first transistor M1, the third transistor M3, the seventh transistor M7, the eighth transistor M8 and the ninth transistor M9 are P-type transistors.

Specifically, with continued reference to FIG. 24, a first electrode of the first transistor M1 is connected to the second power supply voltage terminal VSS, a second electrode of the first transistor M1 is connected to a control electrode of the fifth transistor M5 and a control electrode of the eighth transistor M8 as the first input terminal A of the AND gate, and connected to a control electrode of the sixth transistor M6 and a control electrode of the seventh transistor M7 as the second input terminal B of the AND gate. A first electrode and a control electrode of the second transistor M2 are both connected to the reset signal terminal HF_Reset, and a second electrode of the second transistor M2 is connected to the first node. A first electrode of the third transistor M3 is connected to a first power supply voltage terminal VDD and a second terminal of the second capacitor C2, a second electrode of the third transistor M3 is connected to a first terminal of the first capacitor C1 and the first input terminal A of the AND gate, and a control electrode of the third transistor M3 is connected to the first node. A first electrode of the fourth transistor M4 is connected to the second power supply voltage terminal VSS, a second electrode of the fourth transistor M4 is connected to a first electrode of the ninth transistor M9, and a control electrode of the fourth transistor M4 is connected to a data voltage control signal terminal. A first electrode of the fifth transistor M5 is connected to the second power supply voltage terminal VSS, and a second electrode of the fifth transistor M5 is connected to a first electrode of the sixth transistor M6. A second electrode of the sixth transistor M6 is connected to a first electrode of the seventh transistor M7 and a second electrode of the eighth transistor M8 as an output terminal HF_Output of the AND gate, and a control electrode of the sixth transistor M6 is connected to a control electrode of the seventh transistor M7 as the second input terminal B of the AND gate. A second electrode of the seventh transistor M7 and a first electrode of the eighth transistor M8 are connected to each other, and connected to the first power supply voltage terminal VDD. The first electrode of the ninth transistor M9 is connected to the second electrode of the fourth transistor M4 and a first electrode of the tenth transistor M10, a second electrode of the ninth transistor M9 is connected to the first node, and a control electrode of the ninth transistor M9 is connected to the reset signal terminal HF_Reset. A second electrode of the tenth transistor M10 is connected to the second power supply voltage, and a control electrode of the tenth transistor M10 is connected to the first input terminal A of the AND gate. A second terminal of the first capacitor C1 is connected to the second power supply voltage terminal VSS, and the second terminal of the second capacitor C2 is connected to the first node.

The flip-flop circuit in the twenty-fourth example is simulated only as an example where a first power supply voltage is 8V, a second power supply voltage is −8V; in a timing of an input control signal, a high-level signal is 12V, a low-level signal is −12V, a cycle is H=100 μs, and a duty ratio is a low-level signal/a high-level signal=0.1 μs/99.9 μs; in a timing of a reset signal, a high-level signal is 12V, a low-level signal is −20V, a cycle is H=100 μs, and a duty ratio is a low-level signal/a high-level signal=99.9 μs/0.1 μs; a data voltage control signal is Datastep=[−7.55V, −7.5V, −7.45V, −7.4V, −7.3V, −7.2V, −7.1V, −6.9V, −6.7V], a capacitance of the first capacitor C1 is 200 fF and a capacitance of the second capacitor C2 is 2 pF. It should be understood that the above parameters may be adjusted based on actual requirements in use of an actual product.

Next, an operation of the flip-flop circuit in the twenty-fourth example is described. With continued reference to FIG. 24, a step of generating each clock cycle signal of a clock signal by using the flip-flop circuit in the twenty-fourth example includes the following stages.

In a first stage, i.e., an initial stage of the clock cycle, the reset signal written into the reset signal terminal HF_Reset is a high-level signal, so that the first node is reset to 20V, and the third transistor M3 is turned off in this stage.

In a second stage, the reset signal at the reset signal terminal HF_Reset is a low-level signal, so that the second transistor M2 is turned off, the ninth transistor M9 is turned on. The input control signal written into the input control signal terminal HF_Input is a low-level signal, so that the first transistor M1 is turned on. At this time, both the first input terminal A and the second input terminal B of the AND gate are provided with the second power supply voltage, so that the fifth transistor M5 and the sixth transistor M6 are turned off, the seventh transistor M7 and the eighth transistor M8 are turned on, and the output terminal HF_Output of the AND gate outputs a high-level signal. At the same time, the data voltage control signal written into the data voltage control signal terminal Datastep is written into the control electrode of the fourth transistor M4, and a discharging speed for the first node is controlled by controlling a turn-on degree of the fourth transistor M4.

In a third stage, after a duration t elapses, the control electrode of the third transistor M3 is discharged by the fourth transistor M4 to a voltage of the potential at the first node minus the first power supply voltage being less than a threshold voltage of the third transistor M3, that is, VQ-VDD<Vth, which turns on the third transistor M3, so that the first power supply voltage passes through the third transistor M3 to the first input terminal A of the AND gate, which therefore has the first power supply voltage, that is, a voltage at the first input terminal A of the AND gate is a high-level signal, so that the fifth transistor M5 is turned on. At this time, the output terminal HF_Output of the AND gate outputs a low-level signal.

In a fourth stage, the reset signal at the reset signal terminal HF_Reset is a low-level signal, and the first node is reset to 20V. In this stage, the third transistor M3 is turned off, the first input terminal A of the AND gate retains a high-level signal, so that the fifth transistor M5 is turned on. The output terminal HF_Output still outputs the low-level signal.

It can be seen that the turn-on degree of the fourth transistor M4 is controlled through the data voltage control signal, to control the discharging speed for the first node. The control electrode of the third transistor M3 is discharged by the fourth transistor M4 for a duration during which the potential at the first node minus the first power supply voltage is less than a threshold voltage of the third transistor M3, that is, a duration during which the output terminal HF_Output of the AND gate outputs a high-level signal. The clock signals with different duty ratios may be obtained by adjusting a magnitude of the data voltage control signal.

For the flip-flop circuit in each of the twenty-four examples described above, each transistor may be made of any one of amorphous silicon, polysilicon, low-temperature polysilicon, or oxide.

The simulation conditions in the examples are as above, and each transistor has a width-to-length ratio W/L=5/5.

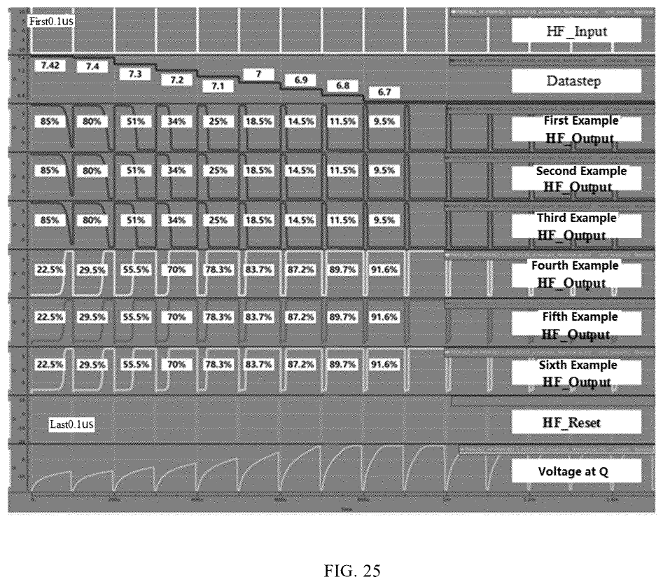

Referring to FIG. 25, it can be seen from the schematic diagram showing simulation results of the flip-flop circuit in each of the first example to the sixth example that with the data voltage control signal Datastep=[7.42V, 7.4V, 7.3V, 7.2V, 7.1V, 7V, 6.9V, 6.8V, 6.7V], a corresponding generated clock cycle has the following duty ratio (a high voltage/a cycle H):[85%, 80%, 51%, 34%, 25%, 18.5%, 14.5%, 11.5%, 9.5%] in each of the first example to the third example; [22.5%, 29.5%, 55.5%, 70%, 78.3%, 83.7%, 87.2%, 89.7%, 91.6%] in each of the fourth example to the sixth example.

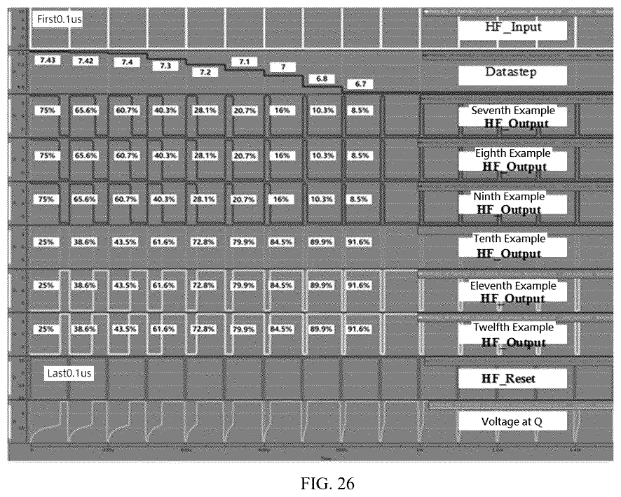

Referring to FIG. 26, it can be seen from the schematic diagram showing simulation results of the flip-flop circuit in each of the seventh example to the twelfth example that with the data voltage control signal Datastep=[7.43V, 7.42V, 7.4V, 7.3V, 7.2V, 7.1V, 7V, 6.8V, 6.7V], a corresponding generated clock cycle has the following duty ratio (a high voltage/a cycle H):[75%, 65.6%, 60.7%, 40.3%, 28.1%, 20.7%, 16%, 10.3%, 8.5%] in each of the seventh example to the ninth example; [25%, 38.6%, 43.5%, 61.6%, 72.8%, 29.9%, 84.5%, 89.9%, 91.6%] in each of the tenth example to the twelfth example.

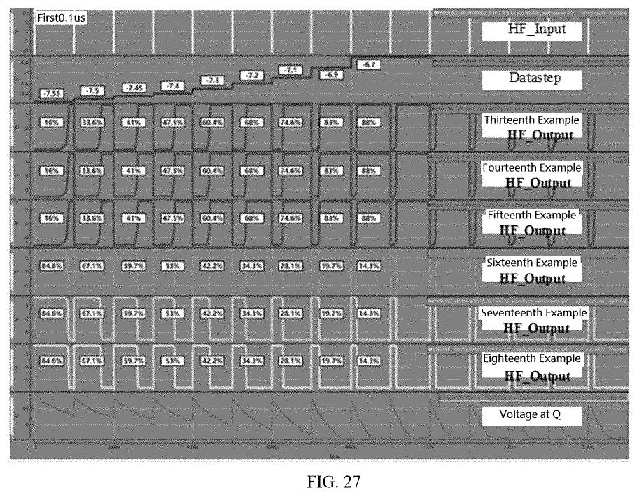

Referring to FIG. 27, it can be seen from the schematic diagram showing simulation results of the flip-flop circuit in each of the thirteenth example to the eighteenth example that with the data voltage control signal Datastep=[−7.55V, −7.5V, −7.45V, −7.4V, −7.3V, −7.2V, −7.1V, −6.9V, −6.7V], a corresponding generated clock cycle has the following duty ratio (a high voltage/a cycle H):[16%, 33.6%, 41%, 47.5%, 60.4%, 68%, 74.6%, 83%, 88%] in each of the thirteenth example to the fifteenth example; [84.6%, 67.1%, 59.7%, 53%, 42.2%, 34.3%, 28.1%, 19.7%, 14.3%] in each of the sixteenth example to the eighteenth example.

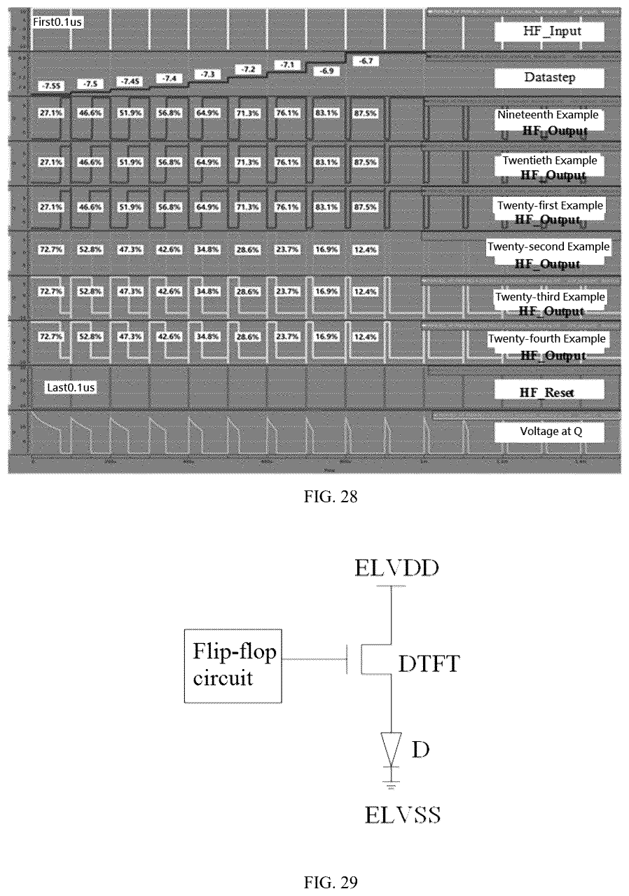

Referring to FIG. 28, it can be seen from the schematic diagram showing simulation results of the flip-flop circuit in each of the nineteenth example to the twenty-fourth example that with the data voltage control signal Datastep=[−7.55V, −7.5V, −7.45V, −7.4V, −7.3V, −7.2V, −7.1V, −6.9V, −6.7V], a corresponding generated clock cycle has the following duty ratio (a high voltage/a cycle H):[27.1%, 46.6%, 51.9%, 56.8%, 64.9%, 71.3%, 76.1%, 83.1%, 87.5%] in each of the nineteenth example to the twenty-first example; [72.7%, 52.8%, 47.3%, 42.6%, 34.8%, 28.6%, 23.7%, 16.9%, 12.4%] in each of the twenty-second example to the twenty-fourth example.

FIG. 29 is a schematic diagram of a pixel driving circuit according to an embodiment of the present disclosure. As shown in FIG. 29, in a second aspect, the embodiment of the present disclosure provides a pixel driving circuit, including a driving transistor DTFT and a flip-flop circuit connected to a control electrode of the driving transistor. The flip-flop circuit may be the flip-flop circuit in any one of the above examples. A first electrode of the driving transistor DTFT is connected to a first driving power supply terminal, a second electrode of the driving transistor DTFT is connected to a first electrode of a light emitting device to be driven, and a second electrode of the light emitting device to be driven is connected to a second driving power terminal. The driving circuit has a simple structure, so that a voltage at the first driving power supply terminal is in a range from about 3V to 5V. In some examples, the light emitting device includes, but is not limited to, an LED or an OLED.

For the pixel driving circuit, when the driving transistor DTFT is turned on, a current drives the light emitting device to emit light, and when the driving transistor DTFT is turned off, the light emitting ends. A signal output by the output terminal HF_Output of the AND gate of the flip-flop circuit is written into a control electrode of the driving transistor DTFT of the pixel driving circuit, and a turn-on duration of the driving transistor DTFT is adjusted by adjusting the duty ratio of the clock signal, to realize the gray scale display. When the duty ratio is low, the driving transistor DTFT has the less turn-on duration, so that a light emitting duration is less, to realize a low gray scale display. When the duty ratio is high, the driving transistor DTFT has the great turn-on duration, so that the light emitting duration is great, to realize a high gray scale display. In the embodiment of the present disclosure, in order to realize the gray scale display, it is only necessary for the light emitting device to emit light having a stable brightness at any one or more fixed levels. The low gray scale display is realized by controlling the light emitting duration, so that the problem is avoided that the light emitting device is unstable at a low brightness.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A flip-flop circuit, comprising:
an AND gate having a first input terminal, a second input terminal, and an output terminal, wherein the AND gate is configured to control the output terminal to output a clock signal based on potentials at the first input terminal and the second input terminal, and a potential of the clock signal jumps between a first power supply voltage and a second power supply voltage;
an input control sub-circuit configured to transmit the first power supply voltage or the second power supply voltage to at least one of the first input terminal and the second input terminal in response to an input control signal; and
a duty cycle adjustment sub-circuit configured to adjust a duty cycle of the clock signal in response to a data voltage control signal.

2. The flip-flop circuit of claim 1, wherein the duty cycle adjustment sub-circuit comprises a control module and a duty cycle adjustment module; and a connection node connected between the control module and the duty ratio adjustment sub-circuit is a first node;
the control module is configured to control a potential at the first node through the first power supply voltage or the second power supply voltage in response to the data voltage control signal; and
the duty cycle adjustment module is configured to adjust the duty cycle of the clock signal output by the output terminal based on the potential at the first node.

3. The flip-flop circuit of claim 2, further comprising a reset sub-circuit configured to respond to a reset signal and reset the first node by the reset signal.

4. The flip-flop circuit of claim 3, wherein the reset sub-circuit comprises a second transistor, and
a control electrode of the second transistor is connected to a first electrode of the second transistor and a reset signal terminal, and a second electrode of the second transistor is connected to the first node.

5. The flip-flop circuit of claim 3, wherein the first input terminal of the AND gate is electrically connected to a first power supply voltage terminal through the input control sub-circuit, and the second input terminal of the AND gate is directly connected to the first power supply voltage terminal; and the duty ratio adjustment module is connected to the first input terminal of the AND gate, or
the first input terminal and the second input terminal of the AND gate are connected to a first power supply voltage terminal through the input control sub-circuit.

6. (canceled)

7. The flip-flop circuit of claim 5, wherein the input control sub-circuit comprises a first transistor; the duty ratio adjustment module comprises a third transistor, a first capacitor and a second capacitor; the control module comprises a fourth transistor; the first transistor has the same switching characteristics as the third transistor, and switching characteristics of the third transistor and switching characteristics of the fourth transistor are opposite to each other;
a control electrode of the first transistor is connected to an input control signal terminal, a first electrode of the first transistor is connected to the first power supply voltage terminal, and a second electrode of the first transistor is connected to the first input terminal;
a control electrode of the third transistor is electrically connected to the first node and a first terminal of the second capacitor, a first electrode of the third transistor is connected to a second power supply voltage terminal and a second terminal of the second capacitor, and a second electrode of the third transistor is connected to a first terminal of the first capacitor and the first input terminal of the AND gate; and a second terminal of the first capacitor is connected to the first power supply voltage terminal or the second power supply voltage terminal; and
a control electrode of the fourth transistor is connected to a data voltage control signal terminal, a first electrode of the fourth transistor is connected to the first power supply voltage terminal, and a second electrode of the fourth transistor is connected to the first node.

8. The flip-flop circuit of claim 5, wherein the input control sub-circuit comprises a first transistor; the duty ratio adjustment module comprises a third transistor, a first capacitor and a second capacitor; the control module comprises a fourth transistor, a ninth transistor and a tenth transistor; switching characteristics of the first transistor, the third transistor and the ninth transistor are the same, and the switching characteristics of the third transistor are opposite to those of the fourth transistor and the tenth transistor;
a control electrode of the first transistor is connected to an input control signal terminal, a first electrode of the first transistor is connected to the first power supply voltage terminal, and a second electrode of the first transistor is connected to the first input terminal;
a control electrode of the third transistor is electrically connected to the first node and a first terminal of the second capacitor, a first electrode of the third transistor is connected to a second power supply voltage terminal, and a second electrode of the third transistor is connected to a first terminal of the first capacitor and the first input terminal of the AND gate; a second terminal of the first capacitor is connected to the first power supply voltage terminal or the second power supply voltage terminal, and a second terminal of the second capacitor is connected to the second power supply voltage terminal;
a control electrode of the fourth transistor is connected to a data voltage control signal terminal, a first electrode of the fourth transistor is connected to the first power supply voltage terminal and a second electrode of the tenth transistor, and a second electrode of the fourth transistor is connected to a first electrode of the ninth transistor and a first electrode of the tenth transistor;
a control electrode of the ninth transistor is connected to a reset signal terminal, and a second electrode of the ninth transistor is connected to the first node; and
a control electrode of the tenth transistor is connected to the first input terminal of the AND gate.

9. The flip-flop circuit of claim 3, wherein the first input terminal of the AND gate is directly connected to the first power supply voltage terminal, and the second input terminal of the AND gate is electrically connected to the first power supply voltage terminal through the input control sub-circuit; and the duty ratio adjustment module is electrically connected to the second input terminal of the AND gate.

10. The flip-flop circuit of claim 9, wherein the input control sub-circuit comprises a first transistor; the duty ratio adjustment module comprises a third transistor, a first capacitor and a second capacitor; the control module comprises a fourth transistor; the first transistor has the same switching characteristics as the third transistor, and switching characteristics of the third transistor and switching characteristics of the fourth transistor are opposite to each other;
a control electrode of the first transistor is connected to an input control signal terminal, a first electrode of the first transistor is connected to the first power supply voltage terminal, and a second electrode of the first transistor is connected to the second input terminal;
a control electrode of the third transistor is electrically connected to the first node and a first terminal of the second capacitor, a first electrode of the third transistor is connected to a second power supply voltage terminal, and a second electrode of the third transistor is connected to a first terminal of the first capacitor and the first input terminal of the AND gate; a second terminal of the first capacitor is connected to the second power supply voltage terminal, and a second terminal of the second capacitor is connected to the second power supply voltage terminal; and
a control electrode of the fourth transistor is connected to a data voltage control signal terminal, a first electrode of the fourth transistor is connected to the first power supply voltage terminal, and a second electrode of the fourth transistor is connected to the first node.

11. The flip-flop circuit of claim 9, wherein the input control sub-circuit comprises a first transistor; the duty ratio adjustment module comprises a third transistor, a first capacitor and a second capacitor; the control module comprises a fourth transistor, a ninth transistor and a tenth transistor; switching characteristics of the first transistor, the third transistor and the ninth transistor are the same, and the switching characteristics of the third transistor are opposite to those of the fourth transistor and the tenth transistor;
a control electrode of the first transistor is connected to an input control signal terminal, a first electrode of the first transistor is connected to the first power supply voltage terminal, and a second electrode of the first transistor is connected to the second input terminal;
a control electrode of the third transistor is electrically connected to the first node and a first terminal of the second capacitor, a first electrode of the third transistor is connected to the second power supply voltage terminal, and a second electrode of the third transistor is connected to a first terminal of the first capacitor and the second input terminal of the AND gate; a second terminal of the first capacitor is connected to the first power supply voltage terminal or the second power supply voltage terminal, and a second terminal of the second capacitor is connected to the second power supply voltage terminal;
a control electrode of the fourth transistor is connected to a data voltage control signal terminal, a first electrode of the fourth transistor is connected to the first power supply voltage terminal and a second electrode of the tenth transistor, and a second electrode of the fourth transistor is connected to a first electrode of the ninth transistor and a first electrode of the tenth transistor;
a control electrode of the ninth transistor is connected to a reset signal terminal, and a second electrode of the ninth transistor is connected to the first node; and
a control electrode of the tenth transistor is connected to the second input terminal of the AND gate.

12. The flip-flop circuit of claim 5, wherein the AND gate comprises a fifth transistor, a sixth transistor, a seventh transistor, and an eighth transistor; switching characteristics of the fifth transistor and the sixth transistor are the same, switching characteristics of the seventh transistor and the eighth transistor are the same, and the switching characteristics of the fifth transistor and the seventh transistor are opposite to each other;
a control electrode of the fifth transistor is connected to a control electrode of the eighth transistor as the first input terminal of the AND gate, a first electrode of the fifth transistor is connected to the first power supply voltage terminal, and a second electrode of the fifth transistor is connected to a first electrode of the sixth transistor;
a control electrode of the sixth transistor is connected to a control electrode of the seventh transistor as the second input terminal of the AND gate, and a second electrode of the sixth transistor is connected to a second electrode of the seventh transistor and a second electrode of the eighth transistor as the output terminal of the AND gate; and
a first electrode of the seventh transistor is connected to a first electrode of the eighth transistor and the second power supply voltage terminal.

13. The flip-flop circuit of claim 5, wherein the AND gate comprises a fifth transistor, a sixth transistor, a seventh transistor, and an eighth transistor; switching characteristics of the fifth transistor and the sixth transistor are the same, switching characteristics of the seventh transistor and the eighth transistor are the same, and the switching characteristics of the fifth transistor and the seventh transistor are opposite to each other;
a control electrode of the fifth transistor is connected to a control electrode of the eighth transistor as the first input terminal of the AND gate, a first electrode of the fifth transistor is connected to the second power supply voltage terminal, and a second electrode of the fifth transistor is connected to a first electrode of the sixth transistor;
a control electrode of the sixth transistor is connected to a control electrode of the seventh transistor as the second input terminal of the AND gate, and a second electrode of the sixth transistor is connected to a second electrode of the seventh transistor and a second electrode of the eighth transistor as the output terminal of the AND gate; and
a first electrode of the seventh transistor is connected to a first electrode of the eighth transistor and the first power supply voltage terminal.

14. The flip-flop circuit of claim 3, wherein the first input terminal of the AND gate is electrically connected to a second power supply voltage terminal through the input control sub-circuit, and the second input terminal of the AND gate is directly connected to a first power supply voltage terminal; and the duty ratio adjustment module is electrically connected to the first input terminal of the AND gate, or
the first input terminal and the second input terminal of the AND gate are electrically connected to a second power supply voltage terminal through the input control sub-circuit.

15. (canceled)

16. The flip-flop circuit of claim 14, wherein the input control sub-circuit comprises a first transistor; the duty ratio adjustment module comprises a third transistor, a first capacitor and a second capacitor; the control module comprises a fourth transistor; the first transistor has the same switching characteristics as the third transistor, and switching characteristics of the third transistor and switching characteristics of the fourth transistor are opposite to each other;
a control electrode of the first transistor is connected to an input control signal terminal, a first electrode of the first transistor is connected to the first power supply voltage terminal, and a second electrode of the first transistor is connected to the first input terminal;
a control electrode of the third transistor is electrically connected to the first node and a first terminal of the second capacitor, a first electrode of the third transistor is connected to the second power supply voltage terminal, and a second electrode of the third transistor is connected to a first terminal of the first capacitor and the first input terminal of the AND gate; a second terminal of the first capacitor is connected to the first power supply voltage terminal or the second power supply voltage terminal, and a second terminal of the second capacitor is connected to the second power supply voltage terminal; and
a control electrode of the fourth transistor is connected to a data voltage control signal terminal, a first electrode of the fourth transistor is connected to the first power supply voltage terminal, and a second electrode of the fourth transistor is connected to the first node.

17. The flip-flop circuit of claim 14, wherein the input control sub-circuit comprises a first transistor; the duty ratio adjustment module comprises a third transistor, a first capacitor and a second capacitor; the control module comprises a fourth transistor, a ninth transistor and a tenth transistor; switching characteristics of the first transistor, the third transistor and the ninth transistor are the same, and the switching characteristics of the third transistor are opposite to those of the fourth transistor and the tenth transistor;
a control electrode of the first transistor is connected to an input control signal terminal, a first electrode of the first transistor is connected to the first power supply voltage terminal, and a second electrode of the first transistor is connected to the first input terminal;
a control electrode of the third transistor is electrically connected to the first node and a first terminal of the second capacitor, a first electrode of the third transistor is connected to the second power supply voltage terminal, and a second electrode of the third transistor is connected to a first terminal of the first capacitor and the first input terminal of the AND gate; a second terminal of the first capacitor is connected to the first power supply voltage terminal or the second power supply voltage terminal, and a second terminal of the second capacitor is connected to the second power supply voltage terminal;
a control electrode of the fourth transistor is connected to a data voltage control signal terminal, a first electrode of the fourth transistor is connected to the first power supply voltage terminal and a second electrode of the tenth transistor, and a second electrode of the fourth transistor is connected to a first electrode of the ninth transistor and a first electrode of the tenth transistor;
a control electrode of the ninth transistor is connected to a reset signal terminal, and a second electrode of the ninth transistor is connected to the first node; and
a control electrode of the tenth transistor is connected to the first input terminal of the AND gate.

18. The flip-flop circuit of claim 3, wherein the first input terminal of the AND gate is connected to a first power supply voltage terminal, and the second input terminal of the AND gate is electrically connected to a second power supply voltage terminal through the input control sub-circuit; and the duty ratio adjustment module is electrically connected to the second input terminal of the AND gate; and
wherein the input control sub-circuit comprises a first transistor; the duty ratio adjustment module comprises a third transistor, a first capacitor and a second capacitor; the control module comprises a fourth transistor; the first transistor has the same switching characteristics as the third transistor, and switching characteristics of the third transistor and switching characteristics of the fourth transistor are opposite to each other;
a control electrode of the first transistor is connected to an input control signal terminal, a first electrode of the first transistor is connected to the first power supply voltage terminal, and a second electrode of the first transistor is connected to the second input terminal;
a control electrode of the third transistor is electrically connected to the first node and a first terminal of the second capacitor, a first electrode of the third transistor is connected to a second power supply voltage terminal, and a second electrode of the third transistor is connected to a first terminal of the first capacitor and the first input terminal of the AND gate; a second terminal of the first capacitor is connected to the second power supply voltage terminal, and a second terminal of the second capacitor is connected to the second power supply voltage terminal; and
a control electrode of the fourth transistor is connected to a data voltage control signal terminal, a first electrode of the fourth transistor is connected to the first power supply voltage terminal, and a second electrode of the fourth transistor is connected to the first node.

19. (canceled)

20. The flip-flop circuit of claim 18, wherein the input control sub-circuit comprises a first transistor; the duty ratio adjustment module comprises a third transistor, a first capacitor and a second capacitor; the control module comprises a fourth transistor, a ninth transistor and a tenth transistor; switching characteristics of the first transistor, the third transistor and the ninth transistor are the same, and the switching characteristics of the third transistor are opposite to those of the fourth transistor and the tenth transistor;
a control electrode of the first transistor is connected to an input control signal terminal, a first electrode of the first transistor is connected to the first power supply voltage terminal, and a second electrode of the first transistor is connected to the second input terminal;
a control electrode of the third transistor is electrically connected to the first node and a first terminal of the second capacitor, a first electrode of the third transistor is connected to the second power supply voltage terminal, and a second electrode of the third transistor is connected to a first terminal of the first capacitor and the second input terminal of the AND gate; a second terminal of the first capacitor is connected to the first power supply voltage terminal or the second power supply voltage terminal, and a second terminal of the second capacitor is connected to the second power supply voltage terminal;
a control electrode of the fourth transistor is connected to a data voltage control signal terminal, a first electrode of the fourth transistor is connected to the first power supply voltage terminal and a second electrode of the tenth transistor, and a second electrode of the fourth transistor is connected to a first electrode of the ninth transistor and a first electrode of the tenth transistor;
a control electrode of the ninth transistor is connected to a reset signal terminal, and a second electrode of the ninth transistor is connected to the first node; and
a control electrode of the tenth transistor is connected to the second input terminal of the AND gate.

21. The flip-flop circuit of claim 14, wherein the AND gate comprises a fifth transistor, a sixth transistor, a seventh transistor, and an eighth transistor; switching characteristics of the fifth transistor and the sixth transistor are the same, switching characteristics of the seventh transistor and the eighth transistor are the same, and the switching characteristics of the fifth transistor and the seventh transistor are opposite to each other;
a control electrode of the fifth transistor is connected to a control electrode of the eighth transistor as the first input terminal of the AND gate, a first electrode of the fifth transistor is connected to the first power supply voltage terminal, and a second electrode of the fifth transistor is connected to a first electrode of the sixth transistor;
a control electrode of the sixth transistor is connected to a control electrode of the seventh transistor as the second input terminal of the AND gate, and a second electrode of the sixth transistor is connected to a second electrode of the seventh transistor and a second electrode of the eighth transistor as the output terminal of the AND gate; and
a first electrode of the seventh transistor is connected to a first electrode of the eighth transistor and the second power supply voltage terminal.

22. The flip-flop circuit of claim 14, wherein the AND gate comprises a fifth transistor, a sixth transistor, a seventh transistor, and an eighth transistor; switching characteristics of the fifth transistor and the sixth transistor are the same, switching characteristics of the seventh transistor and the eighth transistor are the same, and the switching characteristics of the fifth transistor and the seventh transistor are opposite to each other;
a control electrode of the fifth transistor is connected to a control electrode of the eighth transistor as the first input terminal of the AND gate, a first electrode of the fifth transistor is connected to the second power supply voltage terminal, and a second electrode of the fifth transistor is connected to a first electrode of the sixth transistor;
a control electrode of the sixth transistor is connected to a control electrode of the seventh transistor as the second input terminal of the AND gate, and a second electrode of the sixth transistor is connected to a second electrode of the seventh transistor and a second electrode of the eighth transistor as the output terminal of the AND gate; and
a first electrode of the seventh transistor is connected to a first electrode of the eighth transistor and the second power supply voltage terminal.

23. A pixel driving circuit, comprising a driving transistor and the flip-flop circuit of claim 1; wherein a control electrode of the driving transistor is connected to the flip-flop circuit.
